(19) United States
(12) Patent Application Publication
(10) Pub. No.: US 2024/0096538 A1
(43) Pub. Date: Mar. 21, 2024

(54) TRANSFORMER CHIP AND SIGNAL TRANSMISSION DEVICE

(71) Applicant: Rohm Co., Ltd., Kyoto (JP)

(72) Inventors: Yusuke KITADA, Kyoto (JP); Masahiko ARIMURA, Kyoto (JP); Daiki YANAGISHIMA, Kyoto (JP)

(21) Appl. No.: 18/274,286

(22) PCT Filed: Jan. 12, 2022
(86) PCT No.: PCT/JP2022/000690

§ 371 Date: Jul. 26, 2023

(30) Foreign Application Priority Data
Jan. 29, 2021 (JP) 2021-013027
Oct. 14, 2021 (JP) 2021-168703

(51) Int. Cl. H01F 19/08; H01F 27/28; H01F 27/29

(52) U.S. Cl. CPC H01F 19/08; H01F 27/2804; H01F 27/2885; H01F 27/29; H01F 2019/085

(57) ABSTRACT

A signal transmission device is constituted by a transformer chip having, for example, a first wiring layer, a second wiring layer different from the first wiring layer, a primary winding formed in the first wiring layer, a secondary winding formed in the second wiring layer to be magnetically coupled with the primary winding, and a shield electrode formed to be interposed between the primary and secondary windings.

### TECHNICAL FIELD

The invention disclosed herein relates to transformer chips and signal transmission devices.

### BACKGROUND ART

Signal transmission devices that transmit a pulse signal while isolating between input and output have been in practical use in variety of applications (such as power supply devices and moor driving devices).

One example of conventional technology related to what has just been mentioned is seen in Patent Document 1, identified below, by the present applicant.

### CITATION LIST

### Patent Literature

Patent Document 1: JP-A-2018-011108

### SUMMARY OF INVENTION

### Technical Problem

Inconveniently, conventional signal transmission devices leave room for improvement in terms of reduction of instantaneous transient in-phase noise (what is called common-mode noise) that is superposed on each of the reception pulse signals that are parallelly fed to a secondary-side pulse reception circuit.

In view of the just-mentioned challenge encountered by the present inventors, the invention disclosed herein has as its object to provide signal transmission devices that are less susceptible to common-mode noise and to provide transformer chips for use in them.

### Solution to Problem

According to one aspect of what is disclosed herein, a transformer chip includes: a first wiring layer; a second wiring layer different from the first wiring layer; a primary winding formed in the first wiring layer; a secondary winding formed in the second wiring layer so as to be magnetically coupled with the primary winding; and a shield electrode formed so as to be interposed between the primary and secondary windings.

Other features, elements, steps, benefits, and characteristics of the invention disclosed herein will become clear through the following description of embodiments for implementing it, in conjunction with the accompanying drawings.

### Advantageous Effects of Invention

According to the invention disclosed herein, it is possible to provide signal transmission devices that are less susceptible to common-mode noise.

### BRIEF DESCRIPTION OF DRAWINGS

FIG. 1 is a diagram illustrating the basic configuration of a signal transmission device.

FIG. 2 is a diagram showing a potential variation occurring between GND1 and GND2.

FIG. 3 is a diagram showing one example of malfunctioning ascribable to common-mode noise.

FIG. 4 is a diagram showing the principle of how a signal transmission fault occurs (an ideal transformer in response to a regular signal).

FIG. 5 is a diagram showing the principle of how a signal transmission fault occurs (an ideal transformer in response to CM noise).

FIG. 6 is a diagram showing the principle of how a signal transmission fault occurs (a real transformer in response to a regular signal).

FIG. 7 is a diagram showing the principle of how a signal transmission fault occurs (a real transformer in response to CM noise).

FIG. 8 is a diagram showing an example of a noise canceller introduced.

FIG. 9 is a diagram showing one example of noise cancellation operation.

FIG. 10 is a diagram illustrating the basic structure of a transformer chip.

FIG. 11 a perspective view of a semiconductor device used as a two-channel transformer chip.

FIG. 12 is a plan view of the semiconductor device shown in FIG. 11.

FIG. 13 is a plan view of a layer in the semiconductor device shown in FIG. 11 where low-potential coils are formed.

FIG. 14 is a plan view of a layer in the semiconductor device shown in FIG. 11 where high-potential coils are formed.

FIG. 15 is a cross-sectional view taken along line VIII-VIII shown in FIG. 14.

FIG. 16 is a cross-sectional view taken along line IX-IX shown in FIG. 14.

FIG. 17 is an enlarged view of region X shown in FIG. 14.

FIG. 18 is an enlarged view of region XI shown in FIG. 14.

FIG. 19 is an enlarged view of region XII shown in FIG. 14.

FIG. 20 is an enlarged view (showing a separation structure) of region XIII shown in FIG. 7 FIG. 15, showing a separation structure.

FIG. 21 is a diagram schematically showing an example of the layout of a transformer chip.

FIG. 22 is a diagram showing an example of shield electrodes introduced.

FIG. 23 is a diagram showing the vertical structure of a transformer chip provided with shield electrodes.

FIG. 24 is a diagram showing the noise reduction effect of shield electrodes introduced.

FIG. 25 is a diagram showing the relationship of the layout of shield electrodes (plain solid) with signal transmission performance.

FIG. 26 is a diagram showing the relationship of the layout of shield electrodes (O-shaped) with signal transmission performance.

FIG. 27 is a diagram showing the relationship of the layout of shield electrodes (C-shaped) with signal transmission performance.

FIG. 28 is a diagram showing a first exemplary planar layout (C-shaped) of a shield electrode.

FIG. 29 is a diagram showing a second exemplary planar layout (C-shaped, variable dimensions) of a shield electrode.

FIG. 30 is a diagram showing a third exemplary planar layout (O-shaped) of a shield electrode.

FIG. 31 is a diagram showing a fourth exemplary planar layout (single continuous stroke) of a shield electrode.

FIG. 32 is a diagram showing a first exemplary sectional structure of primary and secondary windings and shield electrodes.

FIG. 33 is a diagram showing a second exemplary sectional structure of primary and secondary windings and shield electrodes.

FIG. 34 is a diagram showing a third exemplary sectional structure of primary and secondary windings and shield electrodes.

FIG. 35 is a diagram showing a fourth exemplary sectional structure of primary and secondary windings and shield electrodes.

FIG. 36 is a diagram showing a fifth exemplary sectional structure of primary and secondary windings and shield electrodes.

FIG. 37 is a diagram showing the relationship of the presence or absence of shield electrodes with the coil-to-coil capacitance.

FIG. 38 is a diagram showing a planar layout of pads and a coil.

FIG. 39 is a diagram showing a first planar layout of a shield electrode that overlaps the coil in FIG. 38.

FIG. 40 is a diagram having FIGS. 38 and 39 overlaid on each other.

FIG. 41 is a diagram showing a second planar layout of a shield electrode that overlaps the coil in FIG. 38.

FIG. 42 is a diagram having FIGS. 38 and 41 overlaid on each other.

### DESCRIPTION OF EMBODIMENTS

<Signal Transmission Device (Basic Configuration)>

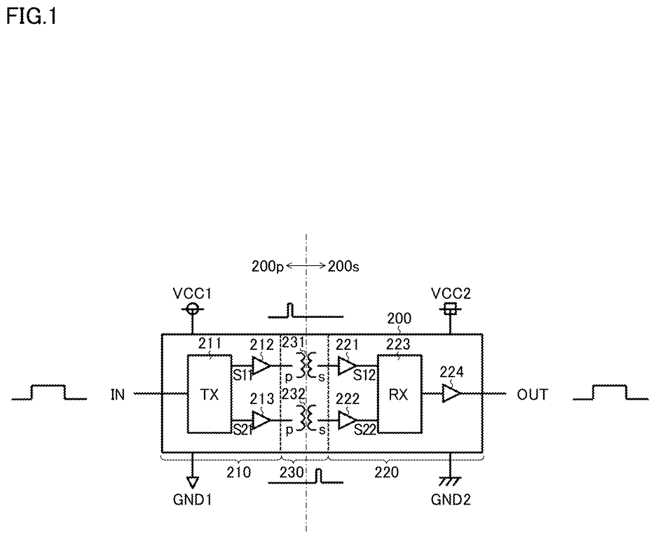

FIG. 1 is a diagram illustrating the basic configuration of a signal transmission device. The signal transmission device 200 of this configuration example is a semiconductor integrated circuit device (what is generally called an isolated gate driver IC) that, while isolating between a primary circuit system 200p (VCC1-GND1 system) and a secondary circuit system 200s (VCC2-GND2 system), transmits a pulse signal from the primary circuit system 200p to the secondary circuit system 200s to drive the gate of a switching device (unillustrated) provided in the secondary circuit system 200s. The signal transmission device 200 has, for example, a controller chip 210, a driver chip 220, and a transformer chip 230 sealed in a single package.

The controller chip 210 is a semiconductor chip that operates by being supplied with a supply voltage VCC1 (e.g., seven volts at the maximum with respect to GND1). The controller chip 210 has, for example, a pulse transmission circuit 211 and buffers 212 and 213 integrated in it.

The pulse transmission circuit 211 is a pulse generator that generates transmission pulse signals S11 and S21 according to an input pulse signal IN. More specifically, when indicating that the input pulse signal IN is at high level, the pulse transmission circuit 211 pulse-drives (outputs a single or a plurality of pulses in) the transmission pulse signal S11; when indicating that the input pulse signal IN is at low level, the pulse transmission circuit 211 pulse-drives the transmission pulse signal S21. That is, the pulse transmission circuit 211 pulse-drives either the transmission pulse signal S11 or S21 according to the logic level of the input pulse signal IN.

The buffer 212 receives the transmission pulse signal S11 from the pulse transmission circuit 211, and pulse-drives the transformer chip 230 (more specifically, a transformer 231).

The buffer 213 receives the transmission pulse signal S21 from the pulse transmission circuit 211, and pulse-drives the transformer chip 230 (more specifically, a transformer 232).

The driver chip 220 is a semiconductor chip that operates by being supplied with a supply voltage VCC2 (e.g., 30 volts at the maximum with respect to GND2). The driver chip 220 has, for example, buffers 221 and 222, a pulse reception circuit 223, and a driver 224 integrated in it.

The buffer 221 performs waveform shaping on a reception pulse signal S12 induced in the transformer chip 230 (specifically, the transformer 231), and outputs the result to the pulse reception circuit 223.

The buffer 222 performs waveform shaping on a reception pulse signal S22 induced in the transformer chip 230 (specifically, the transformer 232), and outputs the result to the pulse reception circuit 223.

According to the reception pulse signals S12 and S22 fed to it via the buffers 221 and 222, the pulse reception circuit 223 drivers the driver 224 to generate an output pulse signal OUT. More specifically, the pulse reception circuit 223 drives the driver 224 to raise the output pulse signal OUT to high level in response to the reception pulse signal S12 being pulse-driven and to drop the output pulse signal OUT to low level in response to the reception pulse signal S22 being pulse-driven. That is, the pulse reception circuit 223 switches the logic level of the output pulse signal OUT according to the logic level of the input pulse signal IN. As the pulse reception circuit 223, for example, an RS flip-flop can be suitably used.

The driver 224 generates the output pulse signal OUT under the driving and control of the pulse reception circuit 223.

The transformer chip 230, while isolating between the controller chip 210 and the driver chip 220 on a direct-current basis using the transformers 231 and 232, outputs the transmission pulse signals S11 and S21 fed to the transformer chip 230 from the pulse transmission circuit 211 to, as the reception pulse signals S12 and S22, the pulse reception circuit 223. In the present description, “isolating on a direct-current basis” means leaving two elements to be isolated from each other unconnected by a conductor.

More specifically, the transformer 231 outputs, according to the transmission pulse signal S11 fed to the primary coil 231p, the reception pulse signal S12 from the secondary coil 231s. Likewise, the transformer 232 outputs, according to the transmission pulse signal S21 fed to the primary coil 232p, the reception pulse signal S22 from the secondary coil 232s.

In this way, owing to the characteristics of spiral coils used in isolated communication, the input pulse signal IN is split into two transmission pulse signals S11 and S21 (corresponding to a rise signal and a fall signal) to be transmitted via the two transformers 231 and 232 from the primary circuit system 200p to the secondary circuit system 200s.

Note that the signal transmission device 200 of this configuration example has, separately from the controller chip 210 and the driver chip 220, the transformer chip 230 that incorporates the transformers 231 and 232 alone, and those three chips are sealed in a single package.

With this configuration, the controller chip 210 and the driver chip 220 can each be formed by a common low- to middle-withstand-voltage process (with a withstand voltage of several volts to several tens of volts). This eliminates the need for a dedicated high-withstand-voltage process (with a withstand voltage of several kilovolts), and helps reduce manufacturing costs.

The signal transmission device 200 can be employed suitably, for example, in a power supply device or motor driving device in a vehicle-mounted device incorporated in a vehicle. Such a vehicle can be an engine vehicle or an electric vehicle (an xEV such as a BEV [battery electric vehicle], HEV [hybrid electric vehicle], PHEV/PHV [plug-in hybrid electric vehicle/plug-in hybrid vehicle], or FCEV/FCV [fuel cell electric vehicle/fuel cell vehicle]).

Moreover, the controller chip 210 and the driver chip 220 can each be fabricated by a time-proven existing process. This eliminates the need for conducting reliability tests anew, and contributes to a shortened development period and reduced development costs.

Moreover, use of an isolating element other than a transformer (e.g., a photocoupler) can be coped with easily by solely mounting the alternative in place of the transformer chip 230. This eliminates the need for re-developing down to the controller chip 210 and the driver chip 220, and contributes to a shortened development period and reduced development costs.

<Studies on Common-Mode Noise>

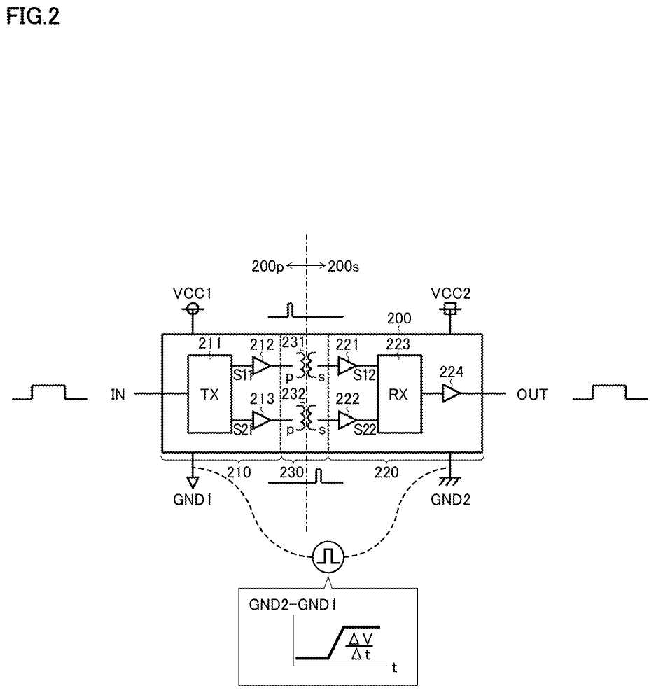

FIG. 2 is a diagram showing a potential variation occurring between GND1 and GND2. As shown there, if a potential variation ΔV/At (i.e., noise) occurs between the ground potential GND1 of the primary circuit system 200p and the ground potential GND2 of the secondary circuit system 200s, noise may appear in the secondary side of the transformer chip 230 and interfere with signal transmission.

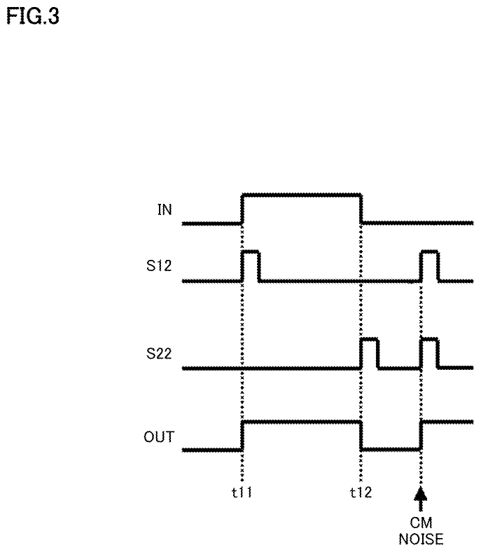

FIG. 3 is a diagram showing one example of malfunctioning ascribable to common-mode noise, and depicts, from top down, the input pulse signal IN, the reception pulse signals S12 and S22, and the output pulse signal OUT.

First, regular pulse signal transmission operation will be described in brief. When at time point t11 the input pulse signal IN rises to high level, the transformer 231 is pulse-driven and thus a regular pulse rises in the reception pulse signal S12. As a result, the output pulse signal OUT rises to high level. When at time point t12 the input pulse signal IN falls to low level, the transformer 232 is pulse-driven and thus a regular pulse rises in the reception pulse signal S22. As a result, the output pulse signal OUT falls to low level.

On the other hand, a false signal ascribable to common-mode noise appears in the transformers 231 and 232 simultaneously. Such a false signal causes the output pulse signal OUT to turn to an unintended logic level. In FIG. 3, although the input pulse signal IN is kept at low level, the output pulse signal OUT rises to high level.

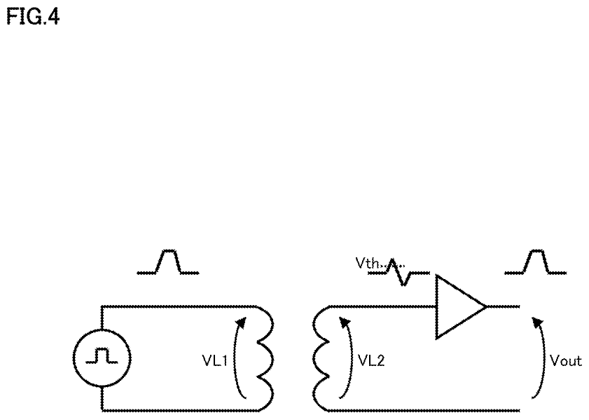

FIGS. 4 to 7 are diagrams showing the principle of how common-mode noise as mentioned above causes a signal transmission fault.

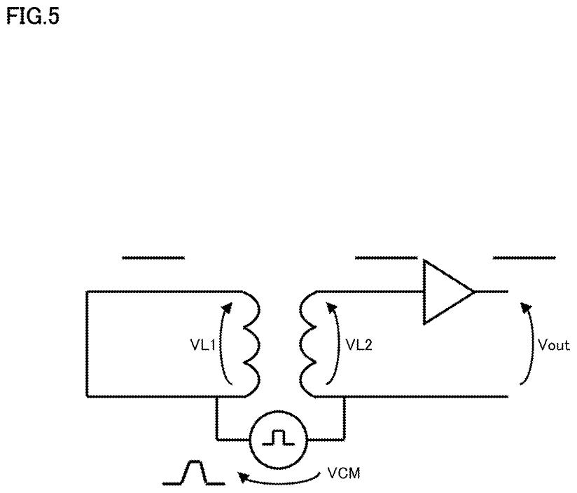

First, with reference to FIGS. 4 and 5, a study will be made of signal transmission using an ideal transformer (a transformer with no inter-coil capacitance between the primary and secondary windings). As shown in FIG. 4, when a regular transmission pulse signal (exciting voltage VL1) is input to the primary winding (corresponding to a primary-side coil) of the transformer, an induced voltage VL2 appears in the secondary winding (corresponding to a secondary-side coil). If the induced voltage VL2 is higher than the threshold voltage Vth of the buffer, a regular reception pulse signal (output voltage Vout) is generated. Even if, as shown in FIG. 5, common-mode noise VCM appears between the primary and secondary circuit systems, no false signal is transmitted to the secondary circuit system.

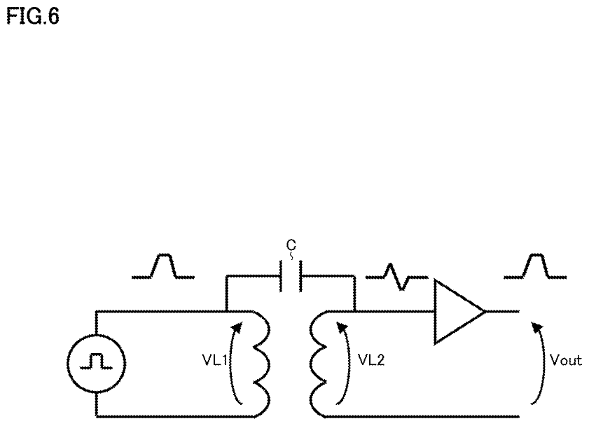

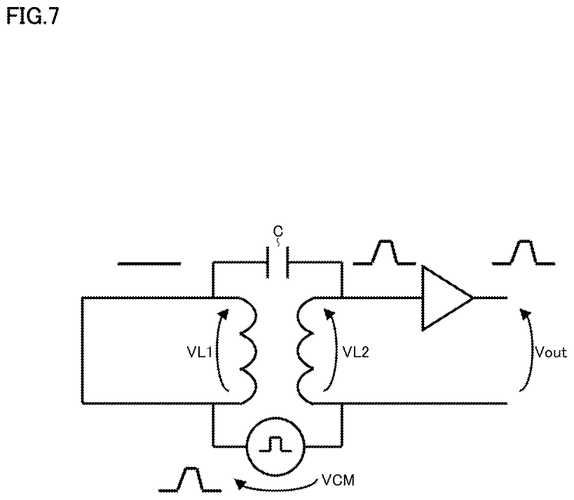

Next, with reference to FIGS. 6 and 7, a study will be made of signal transmission using a real transformer (a transformer with an inter-coil capacitance C between the primary and secondary windings). As shown in FIG. 6, also where a real transformer is used, when a regular transmission pulse signal (exciting voltage VL1) is input to the primary winding (corresponding to a primary-side coil) of the transformer, an induced voltage VL2 appears in the secondary winding (corresponding to a secondary-side coil). If the induced voltage VL2 is higher than the threshold voltage Vth of the buffer, a regular reception pulse signal (output voltage Vout) is generated. Thus, with respect to a regular signal, transmission operation proceeds in much the same way as with an ideal transformer. However, if, as shown in FIG. 7, common-mode noise VCM appears between the primary and secondary circuit systems, in contrast to with an ideal transformer, a false signal is transmitted to the secondary circuit system via the inter-coil capacitance C.

A signal transmission fault ascribable to common-mode noise may lead to malfunctioning or failure of an application. For this reason, the signal transmission device 200 is expected to have high common-mode transient immunity (what is called CMTI).

<Common Measures Against Noise (Introduction of a Noise Canceller)>

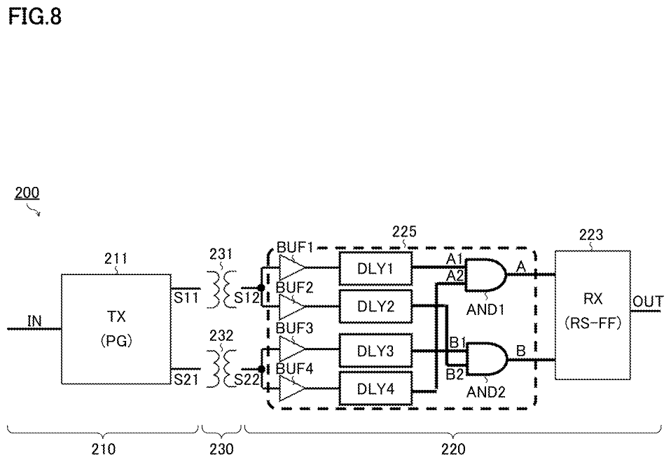

FIG. 8 is a diagram showing an example of introducing a noise canceller (noise masking circuit) in the signal transmission device 200. In the signal transmission device 200 of this configuration example, the driver chip 220 has a noise canceller 225 introduced in the stage preceding the pulse reception circuit 223.

In this configuration example, the noise canceller 225 includes buffers BUF1 to BUF4, delay circuits DLY1 to DLY4, and AND gates AND1 and AND2.

When the reception pulse signal S12 becomes higher than the threshold voltage Vth1, the buffer BUF1 raises its output signal to high level; when the reception pulse signal S12 becomes lower than the threshold voltage Vth1, the buffer BUF1 drops its output signal to low level.

When the reception pulse signal S12 becomes higher than the threshold voltage Vth2 (<Vth1), the buffer BUF2 raises its output signal to high level; when the reception pulse signal S12 becomes lower than the threshold voltage Vth2, the buffer BUF2 drops its output signal to low level.

When the reception pulse signal S22 becomes higher than the threshold voltage Vth1, the buffer BUF3 raises its output signal to high level; when the reception pulse signal S22 becomes lower than the threshold voltage Vth1, the buffer BUF3 drops its output signal to low level.

When the reception pulse signal S22 becomes higher than the threshold voltage Vth2 (<Vth1), the buffer BUF4 raises its output signal to high level; when the reception pulse signal S22 becomes lower than the threshold voltage Vth2, the buffer BUF4 drops its output signal to low level.

The delay circuit DLY1 gives the output signal of the buffer BUF1 a predetermined delay and thereby generates a main signal A1.

The delay circuit DLY2 gives the output signal of the buffer BUF2 a predetermined delay and thereby generates a masking signal B2. For example, the masking signal B2 falls to low level with no delay when the output signal of the buffer BUF2 rises to high level, and rises to high level at the lapse of a predetermined masking period.

The delay circuit DLY3 gives the output signal of the buffer BUF3 a predetermined delay and thereby generates a main signal B1.

The delay circuit DLY4 gives the output signal of the buffer BUF4 a predetermined delay and thereby generates a masking signal A2. For example, the masking signal A2 falls to low level with no delay when the output signal of the buffer BUF4 rises to high level, and rises to high level at the lapse of a predetermined masking period.

The AND gate AND1 performs an AND operation between the main signal A1 and the masking signal A2 and thereby generates a set signal A for the pulse reception circuit 223 (e.g., an RS flip-flop). Accordingly, if A2=L (the logic level during a masking period), A=L (fixed value) and, if A2=H (the logic level during a non-masking period), A=A1.

The AND gate AND2 performs an AND operation between the main signal B1 and the masking signal B2 and thereby generates a reset signal B for the pulse reception circuit 223 (e.g., an RS flip-flop). Accordingly, if B2=L (the logic level during a masking period), B=L (fixed value) and, if B2=H (the logic level during a non-masking period), B=B1.

The pulse reception circuit 223 operates, for example, such that it, when the set signal A rises to high level, sets the output pulse signal OUT to high level and that it, when the reset signal B rises to high level, resets the output pulse signal OUT to low level.

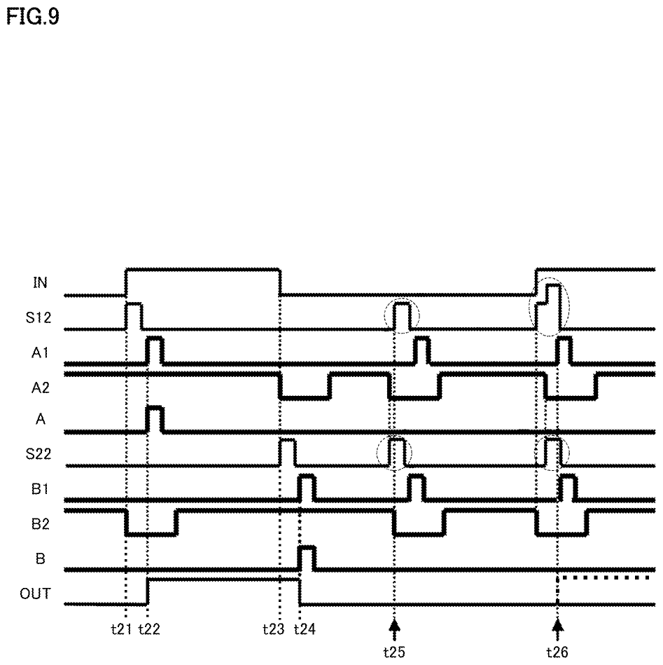

FIG. 9 is a diagram showing one example of noise cancellation operation and depicts, from top down, the input pulse signal IN, the reception pulse signal S12, the main signal A1, the masking signal A2, the set signal A, the reception pulse signal S22, the main signal B1, the masking signal B2, the reset signal B, and the output pulse signal OUT.

First, consider what follows a rise of the input pulse signal IN. When at time point t21 the input pulse signal IN rises to high level, a regular pulse appears in the reception pulse signal S12 and thus, subsequently, at time point t22 a pulse appears in the main signal A1. On the other hand, a rise of the input pulse signal IN to high level does not cause a pulse to appear in the reception pulse signal S22, and thus the masking signal A2 remains at high level. As a result, the main signal A1 is output as it is as the set signal A, and thus the output pulse signal OUT is set to high level,

When at time point t21 a regular pulse appears in the reception pulse signal S12, the masking signal B2 falls to low level, and thus the reset signal B is fixed at low level. Even so, since at a rise of the input pulse signal IN the reset signal B should inherently be kept at low level, no inconsistency arises.

Next, consider what follows a fall of the input pulse signal IN. When at time point t23 the input pulse signal IN falls to low level, a regular pulse appears in the reception pulse signal S22 and thus, subsequently, at time point t24 a pulse appears in the main signal B1. On the other hand, a fall of the input pulse signal IN to low level does not cause a pulse to appear in the reception pulse signal S12, and thus the masking signal B2 remains at high level. As a result, the main signal B1 is output as it is as the reset signal B, and thus the output pulse signal OUT is reset to low level.

When at time point t23 a regular pulse appears in the reception pulse signal S22, the masking signal A2 falls to low level, and thus the set signal A is fixed at low level. Even so, since at a fall of the input pulse signal IN the set signal A should inherently be kept at low level, no inconsistency arises.

Now, consider a case where common-mode noise is superposed on both of the reception pulse signals S12 and S22. At time point t25 a noise pulse rises in each of the reception pulse signals S12 and S22 and, when it becomes higher than the respective threshold voltages Vth1 and Vth2 of the buffers BUF1 to BUF4, a pulse appears in each of the main signals A1 and B1 and the masking signals A2 and B2.

Here, when the masking signal A2 is at low level, irrespective of the logic level of the main signal A1, the set signal A is fixed at low level. Likewise, when the masking signal B2 is at low level, irrespective of the logic level of the main signal B1, the reset signal B is fixed at low level. In this way, it is possible to appropriately eliminate the common-mode noise superposed on both of the reception pulse signals S12 and S22, and thereby to prevent malfunctioning of the output pulse signal OUT.

Inconveniently, as indicated at time point t26, if common-mode noise is superposed, for example, just while the reception pulse signal S12 is being pulse-driven (while a regular pulse is being received), a regular pulse in the main signal A1 is masked by the masking signal A2, and the output pulse signal OUT may not be properly raised to high level.

Though not illustrated specifically, if common-mode noise is superposed just while the reception pulse signal S22 is being pulse-driven, a regular pulse in the main signal B1 is masked by the masking signal B2, and the output pulse signal OUT may not be properly dropped to low level.

Presented below will be a novel structure of the transformer chip 230 with which it is possible to effectively suppresses common-mode noise itself without relying on a noise canceller 225.

<Transformer Chip (Basic Structure)>

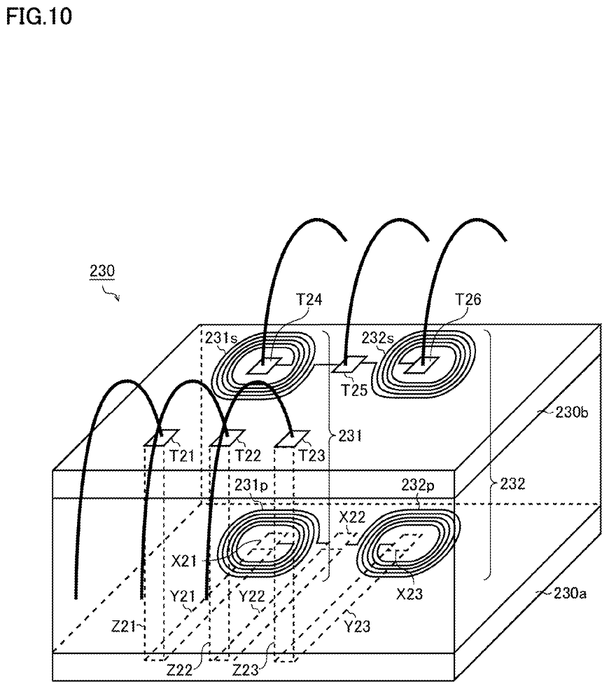

First, the basic structure of the transformer chip 230 will be described. FIG. 10 is a diagram showing the basic structure of the transformer chip 230. In the transformer chip 230 shown there, the transformer 231 includes a primary coil 231p and a secondary coil 231s that face each other in the up-down direction; the transformer 232 includes a primary coil 232p and a secondary coil 232s that face each other in the up-down direction.

The primary coils 231p and 232p are both formed in a first wiring layer (lower layer) 230a in the transformer chip 230. The secondary coils 231s and 231s are both formed in a second wiring layer (the upper layer in the diagram) 230b in the transformer chip 230. The secondary coil 231s is disposed right above the primary coil 231p and faces the primary coil 231p; the secondary coil 232s is disposed right above the primary coil 232p and faces the primary coil 232p.

The primary coil 231p is laid in a spiral shape so as to encircle an internal terminal X21 clockwise, starting at the first terminal of the primary coil 231p, which is connected to the internal terminal X21. The second terminal of the primary coil 231p, which corresponds to its end point, is connected to an internal terminal X22. Likewise, the primary coil 232p is laid in a spiral shape so as to encircle an internal terminal X23 anticlockwise, starting at the first terminal of the primary coil 232p, which is connected to the internal terminal X23. The second terminal of the primary coil 232p, which corresponds to its end point, is connected to the internal terminal X22. Incidentally, the internal terminals X21, X22, and X23 are disposed in a straight row in the illustrated order.

The internal terminal X21 is connected, via a wiring Y21 and a via Z21 both conductive, to an external terminal T21 in the second layer 230b. The internal terminal X22 is connected, via a wiring Y22 and a via Z22 both conductive, to an external terminal T22 in the second layer 230b. The internal terminal X23 is connected, via a wiring Y23 and a via Z23 both conductive, to an external terminal T23 in the second layer 230b. The external terminals T21 to T23 are disposed in a straight row and are used for wire-bonding with the controller chip 210.

The secondary coil 231s is laid in a spiral shape so as to encircle an external terminal T24 anticlockwise, starting at the first terminal of the secondary coil 231s, which is connected to the external terminal T24. The second terminal of the secondary coil 231s, which corresponds to its end point, is connected to an external terminal T25. Likewise, the secondary coil 232s is laid in a spiral shape so as to encircle an external terminal T26 clockwise, starting at the first terminal of the secondary coil 232s, which is connected to the external terminal T26. The second terminal of the secondary coil 232s, which corresponds to its end point, is connected to the external terminal T25. The external terminals T24, T25, and T26 are disposed in a straight row in the illustrated order and are used for wire-bonding with the driver chip 220.

The secondary coils 231s and 232s are AC-connected to the primary coils 231p and 232p, respectively, by magnetic coupling, and are DC-isolated from the primary coils 231p and 232p. That is, the driver chip 220 is AC-connected to the controller chip 210 via the transformer chip 230, and is DC-isolated from the controller chip 210 by the transformer chip 230.

<Transformer Chip (Two-Channel Type)>

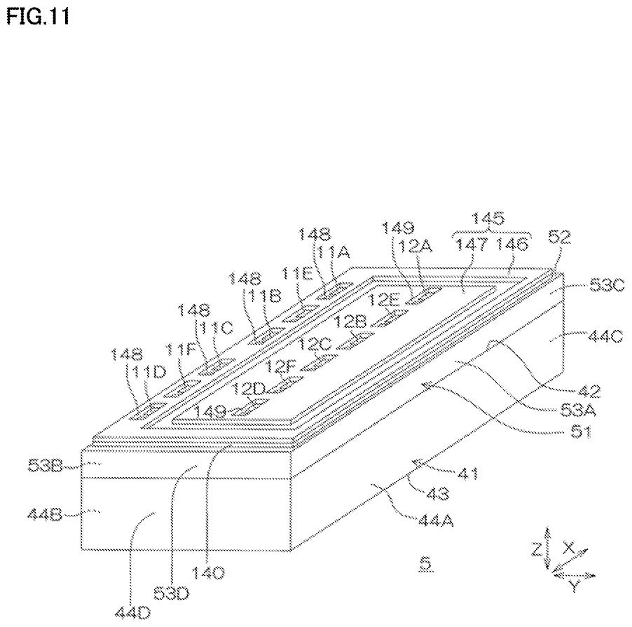

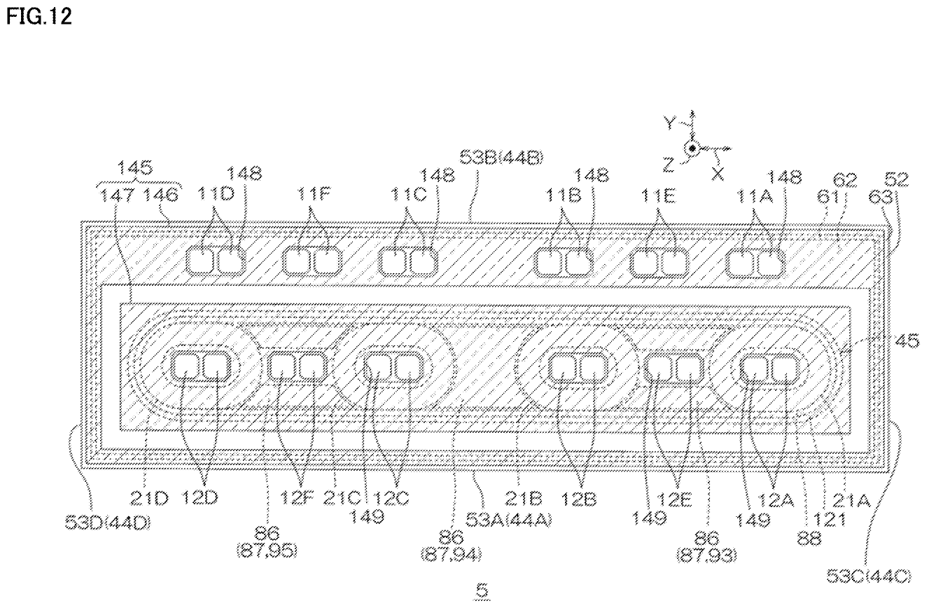

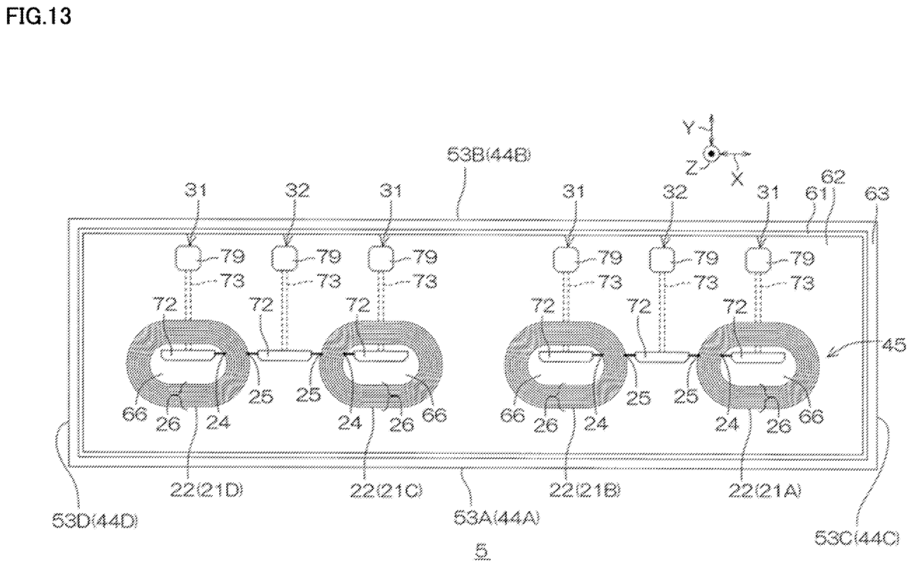

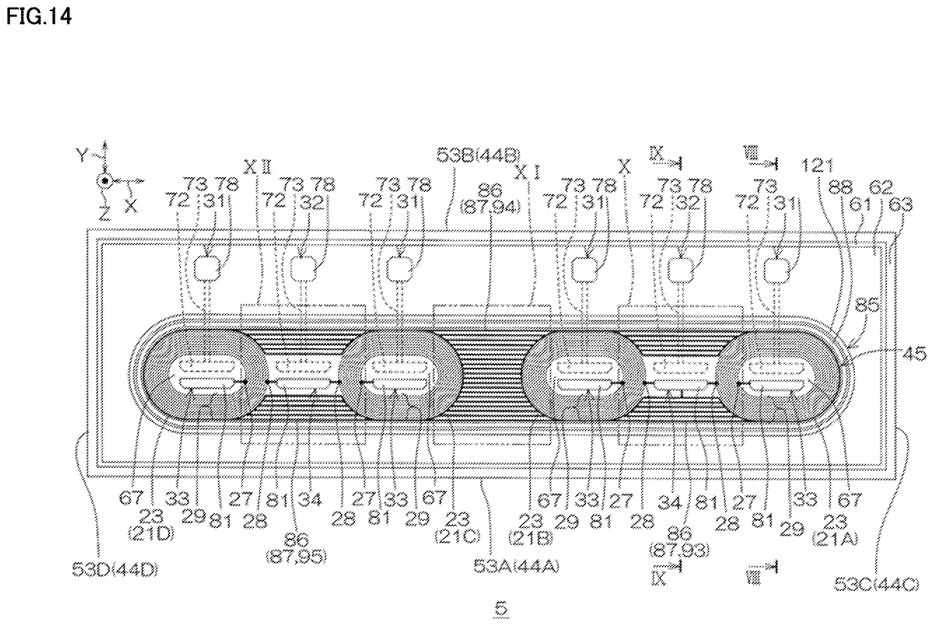

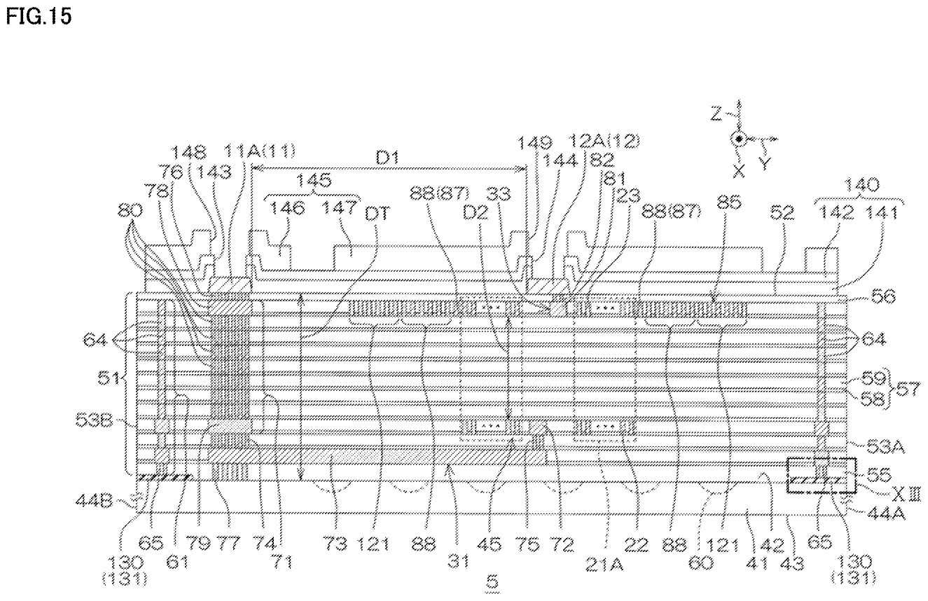

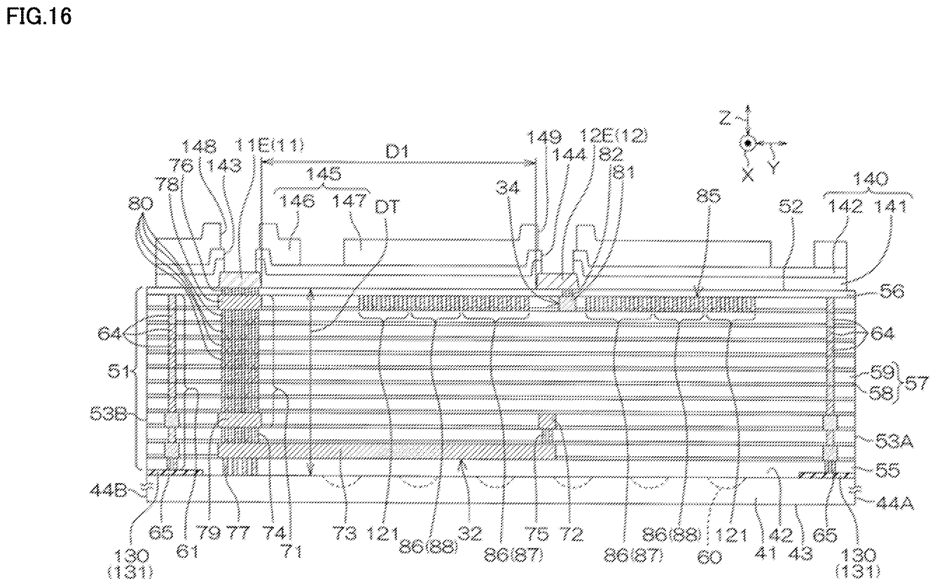

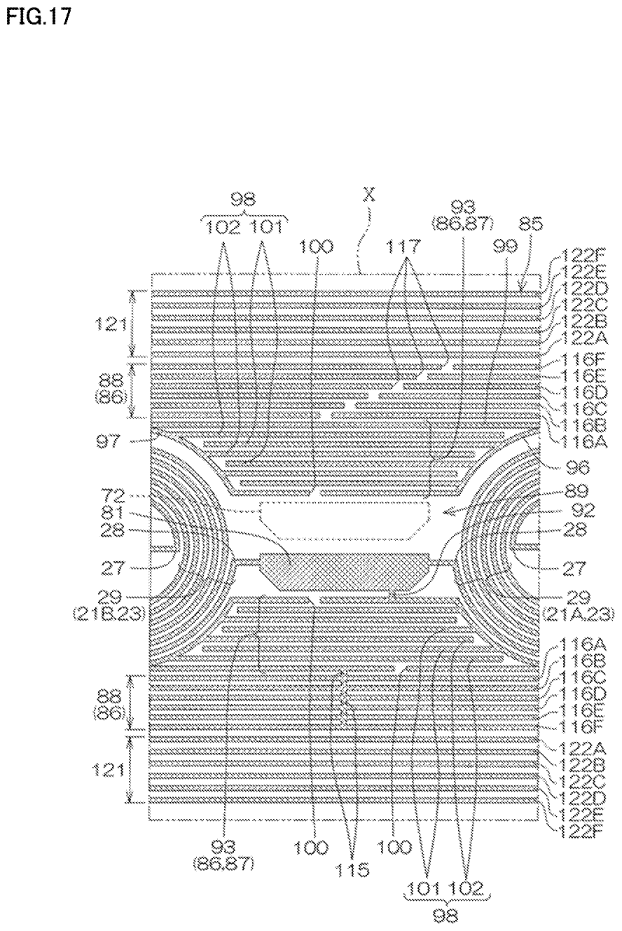

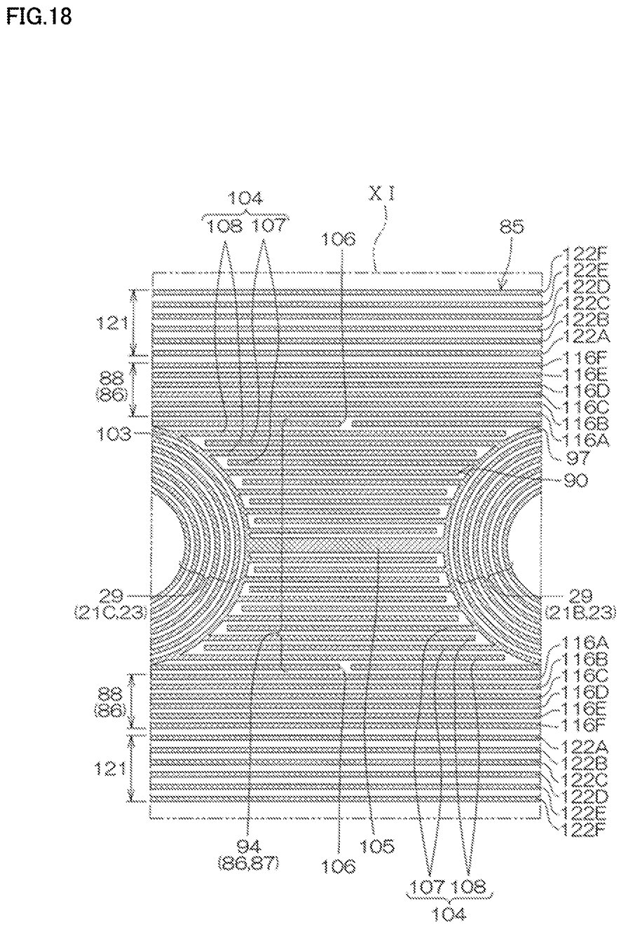

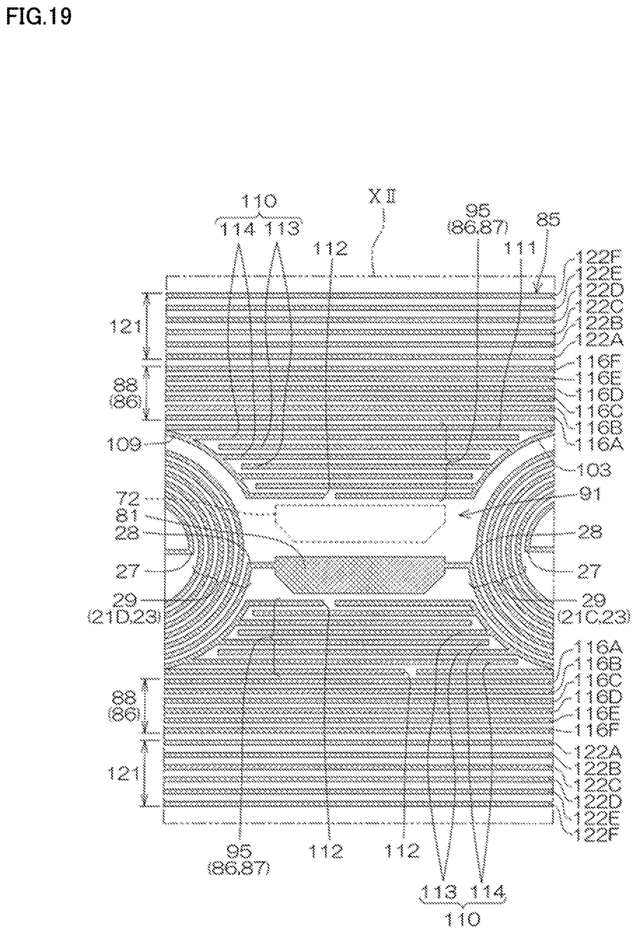

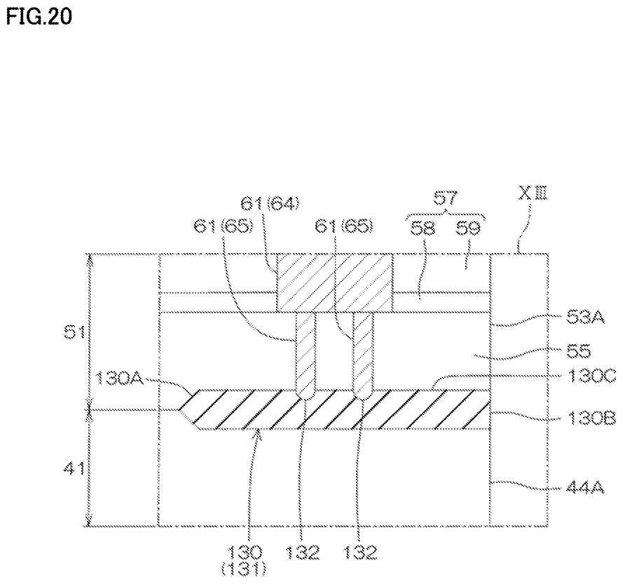

FIG. 11 is a perspective view of a semiconductor device 5 used as a two-channel transformer chip. FIG. 12 is a plan view of the semiconductor device 5 shown in FIG. 11. FIG. 13 is a plan view showing a layer in the semiconductor device 5 shown in FIG. 11 where low-potential coils 22 (corresponding to the primary coils of transformers) are formed. FIG. 14 is a plan view showing a layer in the semiconductor device 5 shown in FIG. 11 where high-potential coils 23 (corresponding to the secondary coils of transformers) are formed. FIG. 15 is a sectional view along line VIII-VIII shown in FIG. 14. FIG. 16 is a sectional view along line IX-IX shown in FIG. 14. FIG. 17 is an enlarged view of region X shown in FIG. 14. FIG. 18 is an enlarged view of region XI shown in FIG. 14. FIG. 19 is an enlarged view of region XII shown in FIG. 14. FIG. 20 is an enlarged view of region XIII shown in FIG. 15, showing a separation structure 130.

Referring to FIGS. 11 to 15, the semiconductor device 5 includes a semiconductor chip 41 in the shape of a rectangular parallelepiped. The semiconductor chip 41 contains at least one of silicon, a wide band gap semiconductor, and a compound semiconductor.

The wide band gap semiconductor is a semiconductor with a band gap larger than that of silicon (about 1.12 eV). Preferably, the wide band gap semiconductor has a band gap of 2.0 eV or more. The wide band gap semiconductor can be SiC (silicon carbide). The compound semiconductor can be a III-V group compound semiconductor. The compound semiconductor can contain at least one of aluminum nitride (AlN), indium nitride (InN), gallium nitride (GaN), and gallium arsenide (GaAs).

In the embodiment, the semiconductor chip 41 includes a semiconductor substrate made of silicon. The semiconductor chip 41 can be an epitaxial substrate that has a stacked structure composed of a semiconductor substrate made of silicon and an epitaxial layer made of silicon. The semiconductor substrate can be of an n-type or p-type conductivity. The epitaxial layer can be of an n-type or p-type.

The semiconductor chip 41 has a first principal surface 42 at one side, a second principal surface 43 at the other side, and chip side walls 44A to 44D that connect the first and second principal surfaces 42 and 43 together. As seen in a plan view from the normal direction Z to them (hereinafter simply expressed as “as seen in a plan view”), the first and second principal surfaces 42 and 43 are each formed in a quadrangular shape (in the embodiment, in a rectangular shape).

The chip side walls 44A to 44D includes a first chip side wall 44A, a second chip side wall 44B, a third chip side wall 44C, and a fourth chip side wall 44D. The first and second chip side walls 44A and 44B constitute the longer sides of the semiconductor chip 41. The first and second chip side walls 44A and 44B extend along a first direction X and face away from each other in a second direction Y. The third and fourth chip side walls 44C and 44D constitute the shorter sides of the semiconductor chip 41. The third and fourth chip side walls 44C and 44D extend in the second direction Y and face away from each other in the first direction X. The chip side walls 44A to 44D have polished surfaces.

The semiconductor device 5 further includes an insulation layer 51 formed on the first principal surface 42 of the semiconductor chip 41. The insulation layer 51 has an insulation principal surface 52 and insulation side walls 53A to 53D. The insulation principal surface 52 is formed in a quadrangular shape (in the embodiment, a rectangular shape) that fits the first principal surface 42 as seen in a plan view. The insulation principal surface 52 extends parallel to the first principal surface 42.

The insulation side walls 53A to 53D include a first insulation side wall 53A, a second insulation side wall 53B, a third insulation side wall 53C, and a fourth insulation side wall 53D. The insulation side walls 53A to 53D extend from the circumferential edge of the insulation principal surface 52 toward the semiconductor chip 41, and are continuous with the chip side walls 44A to 44D. Specifically, the insulation side walls 53A to 53D are formed to be flush with the chip side walls 44A to 44D. The insulation side walls 53A to 53D constitute polished surfaces that are flush with the chip side walls 44A to 44D.

The insulation layer 51 has a stacked structure of multilayer insulation layers that include a bottom insulation layer 55, a top insulation layer 56, and a plurality of (in the embodiment, eleven) interlayer insulation layers 57. The bottom insulation layer 55 is an insulation layer that directly covers the first principal surface 42. The top insulation layer 56 is an insulation layer that constitutes the insulation principal surface 52. The plurality of interlayer insulation layers 57 are insulation layers that are interposed between the bottom and top insulation layers 55 and 56. In the embodiment, the bottom insulation layer 55 has a single-layer structure that contains silicon oxide. In the embodiment, the top insulation layer 56 has a single-layer structure that contains silicon oxide. The bottom and top insulation layers 55 and 56 can each have a thickness of 1 μm or more but 3 μm or less (e.g., about 2 μm).

The plurality of interlayer insulation layers 57 each have a stacked structure that includes a first insulation layer 58 at the bottom insulation layer 55 side and a second insulation layer 59 at the top insulation layer 56 side. The first insulation layer 58 can contain silicon nitride. The first insulation layer 58 is formed as an etching stopper layer for the second insulation layer 59. The first insulation layer 58 can have a thickness of 0.1 μm or more but 1 μm or less (e.g., about 0.3 μm).

The second insulation layer 59 is formed on top of the first insulation layer 58, and contains an insulating material different from that of the first insulation layer 58. The second insulation layer 59 can contain silicon oxide. The second insulation layer 59 can have a thickness of 1 μm or more but 3 μm or less (e.g., about 2 μm). Preferably, the second insulation layer 59 is given a thickness larger than that of the first insulation layer 58.

The insulation layer 51 can have a total thickness DT of 5 μm or more but 50 μm or less. The insulation layer 51 can have any total thickness DT and any number of interlayer insulation layers 57 stacked together, which are adjusted according to the desired dielectric strength voltage (dielectric breakdown withstand voltage). The bottom insulation layer 55, the top insulation layer 56, and the interlayer insulation layers 57 can employ any insulating material, which is thus not limited to any particular insulating material.

The semiconductor device 5 includes a first functional device 45 formed in the insulation layer 51. The first functional device 45 includes one or a plurality of (in the embodiment, a plurality of) transformers 21 (corresponding the transformers mentioned previously). That is, the semiconductor device 5 is a multichannel device that includes a plurality of transformers 21. The plurality of transformers 21 are formed in an inner part of the insulation layer 51, at intervals from the insulation side walls 53A to 53D. The plurality of transformers 21 are formed at intervals from each other in the first direction X.

Specifically, the plurality of transformers 21 include a first transformer 21A, a second transformer 21B, a third transformer 21C, and a fourth transformer 21D that are formed in this order from the insulation side wall 53C side to the insulation side wall 53D side as seen in a plan view. The plurality of transformers 21A to 21D have similar structures. In the following description, the structure of the first transformer 21A will be described as an example. No separate description will be given of the structures of the second, third, and fourth transformers 21B, 21C, and 21D, to which the description of the structure of the first transformer 21A is to be taken to apply.

Referring to FIGS. 13 to 16, the first transformer 21A includes a low-potential coil 22 and a high-potential coil 23. The low-potential coil 22 is formed in the insulation layer 51. The high-potential coil 23 is formed in the insulation layer 51 so as to face the low-potential coil 22 in the normal direction Z. In the embodiment, the low- and high-potential coils 22 and 23 are formed in a region between the bottom and top insulation layers 55 and 56 (i.e., in the plurality of interlayer insulation layer 57).

The low-potential coil 22 is formed in the insulation layer 51, at the bottom insulation layer 55 (semiconductor chip 41) side, and the high-potential coil 23 is formed in the insulation layer 51, at the top insulation layer 56 (insulation principal surface 52) side with respect to the low-potential coil 22. That is, the high-potential coil 23 faces the semiconductor chip 41 across the low-potential coil 22. The low- and high-potential coils 22 and 23 can be disposed at any places. The high-potential coil 23 can face the low-potential coil 22 across one or more interlayer insulation layers 57.

The distance between the low- and high-potential coils 22 and 23 (i.e., the number of interlayer insulation layers 57 stacked together) is adjusted appropriately according to the dielectric strength voltage and electric field strength between the low- and high-potential coils 22 and 23. In the embodiment, the low-potential coil 22 is formed in the third interlayer insulation layer 57 as counted from the bottom insulation layer 55 side. In the embodiment, the high-potential coil 23 is formed in the first interlayer insulation layer 57 as counted from the top insulation layer 56 side.

The low-potential coil 22 is embedded in the interlayer insulation layer 57 so as to penetrate the first and second insulation layers 58 and 59. The low-potential coil 22 includes a first inner end 24, a first outer end 25, and a first spiral portion 26 that is patterned in a spiral shape between the first inner and outer ends 24 and 25. The first spiral portion 26 is patterned in a spiral shape that extends in an elliptical (oval) shape as seen in a plan view. The part of the first spiral portion 26 that forms its inner circumferential edge defines a first inner region 66 that is in an elliptical shape as seen in a plan view.

The first spiral portion 26 can have a number of turns of 5 or more but 30 or less. The first spiral portion 26 can have a width of 0.1 μm or more but 5 μm or less. Preferably, the first spiral portion 26 has a width of 1 μm or more but 3 μm or less. The width of the first spiral portion 26 is defined by its width in the direction orthogonal to the spiraling direction. The first spiral portion 26 has a first winding pitch of 0.1 μm or more but 5 μm or less. Preferably, the first winding pitch is 1 μm or more but 3 μm or less. The first winding pitch is defined by the distance between two parts of the first spiral portion 26 that are adjacent to each other in the direction orthogonal to the spiraling direction.

The first spiral portion 26 can have any winding shape and the first inner region 66 can have any planar shape, which are thus not limited to those shown in FIG. 13 etc. The first spiral portion 26 can be wound in a polygonal shape, such as a triangular or quadrangular shape, or in a circular shape as seen in a plan view. The first inner region 66 can be defined, so as to fit the winding shape of the first spiral portion 26, in a polygonal shape, such as a triangular or quadrangular shape, or in a circular shape as seen in a plan view.

The low-potential coil 22 can contain at least one of titanium, titanium nitride, copper, aluminum, and tungsten. The low-potential coil 22 can have a stacked structure composed of a barrier layer and a body layer. The barrier layer defines a recessed space in the interlayer insulation layer 57. The body layer is embedded in the recess space defined by the barrier layer. The barrier layer can contain at least one of titanium and titanium nitride. The body layer can contain at least one of copper, aluminum, and tungsten.

The high-potential coil 23 is embedded in the interlayer insulation layer 57 so as to penetrate the first and second insulation layers 58 and 59. The high-potential coil 23 includes a second inner end 27, a second outer end 28, and a second spiral portion 29 that is patterned in a spiral shape between the second inner and outer ends 27 and 28. The second spiral portion 29 is patterned in a spiral shape that extends in an elliptical (oval) shape as seen in a plan view. The part of the second spiral portion 29 that forms its inner circumferential edge defines a second inner region 67 that is in an elliptical shape as seen in a plan view in the embodiment. The second inner region 67 in the second spiral portion 29 faces the first inner region 66 in the first spiral portion 26 in the normal direction Z.

The second spiral portion 29 can have a number of turns of 5 or more but 30 or less. The number of turns of the second spiral portion 29 relative to that of the first spiral portion 26 is adjusted according to the target value of voltage boosting. Preferably, the number of turns of the second spiral portion 29 is larger than that of the first spiral portion 26. Needless to say, the number of turns of the second spiral portion 29 can be smaller than or equal to that of the first spiral portion 26.

The second spiral portion 29 can have a width of 0.1 μm or more but 5 μm or less. Preferably, the second spiral portion 29 has a width of 1 μm or more but 3 μm or less. The width of the second spiral portion 29 is defined by its width in the direction orthogonal to the spiraling direction. Preferably, the width of the second spiral portion 29 is equal to the width of the first spiral portion 26.

The second spiral portion 29 can have a second winding pitch of 0.1 μm or more but 5 μm or less. Preferably, the second winding pitch is 1 μm or more but 3 μm or less. The second winding pitch is defined by the distance between two parts of the second spiral portion 29 that are adjacent to each other in the direction orthogonal to the spiraling direction. Preferably, the second winding pitch is equal to the first winding pitch of the first spiral portion 26.

The second spiral portion 29 can have any winding shape and the second inner region 67 can have any planar shape, which are thus not limited to those shown in FIG. 14 etc. The second spiral portion 29 can be wound in a polygonal shape, such as a triangular or quadrangular shape, or in a circular shape as seen in a plan view. The second inner region 67 can be defined, so as to fit the winding shape of the second spiral portion 29, in a polygonal shape, such as a triangular or quadrangular shape, or in a circular shape as seen in a plan view.

Preferably, the high-potential coil 23 is formed of the same conductive material as the low-potential coil 22. That is, preferably, like the low-potential coil 22, the high-potential coil 23 includes a barrier layer and a body layer.

Referring to FIG. 12, the semiconductor device 5 includes a plurality of (in the diagram, twelve) low-potential terminals 11 and a plurality of (in the diagram, twelve) high-potential terminals 12. The plurality of low-potential terminals 11 are electrically connected to the low-potential coils 22 of the corresponding transformers 21A to 21D respectively. The plurality of high-potential terminals 12 are electrically connected to the high-potential coils 23 of the corresponding transformers 21A to 21D respectively.

The plurality of low-potential terminals 11 are formed on the insulation principal surface 52 of the insulation layer 51. Specifically, the plurality of low-potential terminals 11 are formed in a second insulation side wall 53B side region, at an interval from the plurality of transformers 21A to 21D in the second direction Y, and are arrayed at intervals from each other in the first direction X.

The plurality of low-potential terminals 11 include a first low-potential terminal 11A, a second low-potential terminal 11B, a third low-potential terminal 11C, a fourth low-potential terminal 11D, a fifth low-potential terminal 11E, and a sixth low-potential terminal 11F. Actually, in the embodiment, two each of the plurality of low-potential terminals 11A to 11F are formed. The plurality of low-potential terminals 11A to 11F may each include any number of terminals.

The first low-potential terminal 11A faces the first transformer 21A in the second direction Y as seen in a plan view. The second low-potential terminal 11B faces the second transformer 21B in the second direction Y as seen in a plan view. The third low-potential terminal 11C faces the third transformer 21C in the second direction Y as seen in a plan view. The fourth low-potential terminal 11D faces the fourth transformer 21D in the second direction Y as seen in a plan view. The fifth low-potential terminal 11E is formed in a region between the first and second low-potential terminals 11A and 11B as seen in a plan view. The sixth low-potential terminal 11F is formed in a region between the third and fourth low-potential terminals 11C and 11D as seen in a plan view.

The first low-potential terminal 11A is electrically connected to the first inner end 24 of the first transformer 21A (low-potential coil 22). The second low-potential terminal 11B is electrically connected to the first inner end 24 of the second transformer 21B (low-potential coil 22). The third low-potential terminal 11C is electrically connected to the first inner end 24 of the third transformer 21C (low-potential coil 22). The fourth low-potential terminal 11D is electrically connected to the first inner end 24 of the fourth transformer 21D (low-potential coil 22).

The fifth low-potential terminal 11E is electrically connected to the first outer end 25 of the first transformer 21A (low-potential coil 22) and to the first outer end 25 of the second transformer 21B (low-potential coil 22). The sixth low-potential terminal 11F is electrically connected to the first outer end 25 of the third transformer 21C (low-potential coil 22) and to the first outer end 25 of the fourth transformer 21D (low-potential coil 22).

The plurality of high-potential terminals 12 are formed on the insulation principal surface 52 of the insulation layer 51, at an interval from the plurality of low-potential terminals 11. Specifically, the plurality of high-potential terminals 12 are formed in a first insulation side wall 53A side region, at an interval from the plurality of low-potential terminals 11 in the second direction Y, and are arrayed at intervals from each other in the first direction X.

The plurality of high-potential terminals 12 are formed in regions close to the corresponding transformers 21A to 21D, respectively, as seen in a plan view. The high-potential terminals 12 being close to the transformers 21A to 21D means that, as seen in a plan view, the distance between the high-potential terminals 12 and the transformers 21 is smaller than the distance between the low-potential terminals 11 and the high-potential terminals 12.

Specifically, as seen in a plan view, the plurality of high-potential terminals 12 are formed at intervals from each other along the first direction X so as to face the plurality of transformers 21A to 21D along the first direction X. More specifically, as seen in a plan view, the plurality of high-potential terminals 12 are formed at intervals from each other along the first direction X so as to be located in the second inner regions 67 in the high-potential coils 23 and in regions between adjacent high-potential coils 23. As a result, as seen in a plan view, the plurality of high-potential terminals 12 are, along with the transformers 21A to 21D, arrayed in one row along the first direction X.

The plurality of high-potential terminals 12 include a first high-potential terminal 12A, a second high-potential terminal 12B, a third high-potential terminal 12C, a fourth high-potential terminal 12D, a fifth high-potential terminal 12E, and a sixth high-potential terminal 12F. Actually, in the embodiment, two each of the plurality of high-potential terminals 12A to 12F are formed. The plurality of high-potential terminals 12A to 12F may each include any number of terminals.

The first high-potential terminal 12A is formed in the second inner region 67 in the first transformer 21A (high-potential coil 23) as seen in a plan view. The second high-potential terminal 12B is formed in the second inner region 67 in the second transformer 21B (high-potential coil 23) as seen in a plan view. The third high-potential terminal 12C is formed in the second inner region 67 in the third transformer 21C (high-potential coil 23) as seen in a plan view. The fourth high-potential terminal 12D is formed in the second inner region 67 in the fourth transformer 21D (high-potential coil 23) as seen in a plan view. The fifth high-potential terminal 12E is formed in a region between the first and second transformers 21A and 21B as seen in a plan view. The sixth high-potential terminal 12F is formed in a region between the third and fourth transformers 21C and 21D as seen in a plan view.

The first high-potential terminal 12A is electrically connected to the second inner end 27 of the first transformer 21A (high-potential coil 23). The second high-potential terminal 12B is electrically connected to the second inner end 27 of the second transformer 21B (high-potential coil 23). The third high-potential terminal 12C is electrically connected to the second inner end 27 of the third transformer 21C (high-potential coil 23). The fourth high-potential terminal 12D is electrically connected to the second inner end 27 of the fourth transformer 21D (high-potential coil 23).

The fifth high-potential terminal 12E is electrically connected to the second outer end 28 of the first transformer 21A (high-potential coil 23) and to the second outer end 28 of the second transformer 21B (high-potential coil 23). The sixth high-potential terminal 12F is electrically connected to the second outer end 28 of the third transformer 21C (high-potential coil 23) and to the second outer end 28 of the fourth transformer 21D (high-potential coil 23).

Referring to FIGS. 13 to 16, the semiconductor device 5 includes a first low-potential wiring 31, a second low-potential wiring 32, a first high-potential wiring 33, and a second high-potential wiring 34, all formed in the insulation layer 51. Actually, in the embodiment, a plurality of first low-potential wirings 31, a plurality of second low-potential wirings 32, a plurality of first high-potential wirings 33, and a plurality of second high-potential wirings 34 are formed.

The first and second low-potential wirings 31 and 32 hold the low-potential coils 22 of the first and second transformers 21A and 21B at equal potentials. The first and second low-potential wirings 31 and 32 also hold the low-potential coils 22 of the third and fourth transformers 21C and 21D at equal potentials. In the embodiment, the first and second low-potential wirings 31 and 32 hold the low-potential coils 22 of all the transformers 21A to 21D at equal potentials.

The first and second high-potential wirings 33 and 34 hold the high-potential coils 23 of the first and second transformers 21A and 21B at equal potentials. The first and second high-potential wirings 33 and 34 also hold the high-potential coils 23 of the third and fourth transformers 21C and 21D at equal potentials. In the embodiment, the first and second high-potential wirings 33 and 34 hold the high-potential coils 23 of all the transformers 21A to 21D at equal potentials.

The plurality of first low-potential wirings 31 are electrically connected respectively to the corresponding low-potential terminals 11A to 11D and to the first inner ends 24 of the corresponding transformers 21A to 21D (low-potential coils 22). The plurality of first low-potential wirings 31 have similar structures. In the following description, the structure of the first low-potential wiring 31 connected to the first low-potential terminal 11A and to the first transformer 21A will be described as an example. No separate description will be given of the structures of the other first low-potential wirings 31, to which the description of the structure of the first low-potential wiring 31 connected to the first transformer 21A is to be taken to apply.

The first low-potential wiring 31 includes a through wiring 71, a low-potential connection wiring 72, a lead wiring 73, a first connection plug electrode 74, a second connection plug electrode 75, one or a plurality of (in this embodiment, a plurality of) pad plug electrodes 76, and one or a plurality of (in this embodiment, a plurality of) substrate plug electrodes 77.

Preferably, the through wiring 71, the low-potential connection wiring 72, the lead wiring 73, the first connection plug electrode 74, the second connection plug electrode 75, the pad plug electrodes 76, and the substrate plug electrodes 77 are formed of the same conductive material as the low-potential coil 22 and the like. That is, preferably, like the low-potential coil 22 and the like, the through wiring 71, the low-potential connection wiring 72, the lead wiring 73, the first connection plug electrode 74, the second connection plug electrode 75, the pad plug electrodes 76, and the substrate plug electrodes 77 each include a barrier layer and a body layer.

The through wiring 71 penetrates a plurality of interlayer insulation layers 57 in the insulation layer 51 and extends in a columnar shape along the normal direction Z. In the embodiment, the through wiring 71 is formed in a region between the bottom and top insulation layers 55 and 56 in the insulation layer 51. The through wiring 71 has a top end part at the top insulation layer 56 side and a bottom end part at the bottom insulation layer 55 side. The top end part of the through wiring 71 is formed in the same interlayer insulation layer 57 as the high-potential coil 23, and is covered by the top insulation layer 56. The bottom end part of the through wiring 71 is formed in the same interlayer insulation layer 57 as the low-potential coil 22.

In the embodiment, the through wiring 71 includes a first electrode layer 78, a second electrode layer 79, and a plurality of wiring plug electrodes 80. In the through wiring 71, the first and second electrode layers 78 and 79 and the wiring plug electrodes 80 are formed of the same conductive material as the low-potential coil 22 and the like. That is, like the low-potential coil 22 and the like, the first and second electrode layers 78 and 79 and the wiring plug electrodes 80 each include a barrier layer and a body layer.

The first electrode layer 78 constitutes the top end part of the through wiring 71. The second electrode layer 79 constitutes the bottom end part of the through wiring 71. The first electrode layer 78 is formed as an island, and faces the low-potential terminal 11 (first low-potential terminal 11A) in the normal direction Z. The second electrode layer 79 is formed as an island, and faces the first electrode layer 78 in the normal direction Z.

The plurality of wiring plug electrodes 80 are embedded respectively in the plurality of interlayer insulation layers 57 located in a region between the first and second electrode layers 78 and 79. The plurality of wiring plug electrodes 80 are stacked together from the bottom insulation layer 55 to the top insulation layer 56 so as to be electrically connected together, and electrically connect together the first and second electrode layers 78 and 79. The plurality of wiring plug electrodes 80 each have a plane area smaller than the plane area of either of the first and second electrode layers 78 and 79.

The number of layers stacked in the plurality of wiring plug electrodes 80 is equal to the number of layers stacked in the plurality of interlayer insulation layer 57. In the embodiment, six wiring plug electrodes 80 are embedded in interlayer insulation layers 57 respectively, and any number of wiring plug electrodes 80 can be embedded in interlayer insulation layers 57 respectively. Needless to say, one or a plurality of wiring plug electrodes 80 can be formed that penetrates a plurality of interlayer insulation layers 57.

The low-potential connection wiring 72 is formed in the same interlayer insulation layer 57 as the low-potential coil 22, in the first inner region 66 in the first transformer 21A (low-potential coil 22). The low-potential connection wiring 72 is formed as an island, and faces the high-potential terminal 12 (first high-potential terminal 12A) in the normal direction Z. Preferably, the low-potential connection wiring 72 has a plane area larger than the plane area of the wiring plug electrode 80. The low-potential connection wiring 72 is electrically connected to the first inner end 24 of the low-potential coil 22.

The lead wiring 73 is formed in the interlayer insulation layer 57, in a region between the semiconductor chip 41 and the through wiring 71. In the embodiment, the lead wiring 73 is formed in the first interlayer insulation layer 57 as counted from the bottom insulation layer 55. The lead wiring 73 has a first end part at one side, a second end part at the other side, and a wiring part that connects together the first and second end parts. The first end part of the lead wiring 73 is located in a region between the semiconductor chip 41 and the bottom end part of the through wiring 71. The second end part of the lead wiring 73 is located in a region between the semiconductor chip 41 and the low-potential connection wiring 72. The wiring part extends along the first principal surface 42 of the semiconductor chip 41, and extends in the shape of a stripe in a region between the first and second end parts.

The first connection plug electrode 74 is formed in the interlayer insulation layer 57, in a region between the through wiring 71 and the lead wiring 73, and is electrically connected to the through wiring 71 and to the first end part of the lead wiring 73. The second connection plug electrode 75 is formed in the interlayer insulation layer 57, in a region between the low-potential connection wiring 72 and the lead wiring 73, and is electrically connected to the low-potential connection wiring 72 and to the second end part of the lead wiring 73.

The plurality of pad plug electrodes 76 are formed in the top insulation layer 56, in a region between the low-potential terminal 11 (first low-potential terminal 11A) and the through wiring 71, and are electrically connected to the low-potential terminal 11 and to the top end part of the through wiring 71. The plurality of substrate plug electrodes 77 are formed in the bottom insulation layer 55, in a region between the semiconductor chip 41 and the lead wiring 73. In the embodiment, the substrate plug electrodes 77 are formed in a region between the semiconductor chip 41 and the first end part of the lead wiring 73, and are electrically connected to the semiconductor chip 41 and to the first end part of the lead wiring 73.

Referring to FIG. 16, the plurality of second low-potential wirings 32 are connected respectively to the corresponding low-potential terminals 11E and 11F and to the first outer ends 25 of the low-potential coils 22 of the corresponding transformers 21A to 21D. The plurality of second low-potential wirings 32 have similar structures. In the following description, the structure of the second low-potential wiring 32 connected to the fifth low-potential terminal 11E and to the first transformer 21A (second transformer 21B) will be described as an example. No description will be given of the structures of the other second low-potential wirings 32, to which the description of the structure of the second low-potential wiring 32 connected to the first transformer 21A (second transformer 21B) is to be taken to apply.

Like the first low-potential wiring 31, the second low-potential wiring 32 includes a through wiring 71, a low-potential connection wiring 72, a lead wiring 73, a first connection plug electrode 74, a second connection plug electrode 75, a pad plug electrode 76, and a substrate plug electrodes 77. The second low-potential wiring 32 has a similar structure to the first low-potential wiring 31 except that the low-potential connection wiring 72 is connected to the first outer end 25 of the first transformer 21A (low-potential coil 22) and to the first outer end 25 of the second transformer 21B (low-potential coil 22).

The low-potential connection wiring 72 of the second low-potential wiring 32 is formed around the low-potential coil 22 in the same interlayer insulation layer 57 as the low-potential coil 22. Specifically, the low-potential connection wiring 72 is formed in a region between two low-potential coils 22 adjacent to each other as seen in a plan view. The pad plug electrode 76 is formed in the top insulation layer 56, in a region between the low-potential terminal 11 (fifth low-potential terminal 11E) and the low-potential connection wiring 72, and is electrically connected to the low-potential terminal 11 and to the low-potential connection wiring 72.

Referring to FIG. 15, the plurality of first high-potential wirings 33 are connected respectively to the corresponding high-potential terminals 12A to 12D and to the second inner ends 27 of the corresponding transformers 21A to 21D (high-potential coils 23). The plurality of first high-potential wirings 33 have similar structures. In the following description, the structure of the first high-potential wiring 33 connected to the first high-potential terminal 12A and to the first transformer 21A will be described as an example. No description will be given of the structures of the other first high-potential wirings 33, to which the description of the structure of the first high-potential wiring 33 connected to the first transformer 21A is to be taken to apply.

The first high-potential wiring 33 includes a high-potential connection wiring 81 and one or a plurality of (in this embodiment, a plurality of) pad plug electrodes 82. Preferably, the high-potential connection wiring 81 and the pad plug electrodes 82 are formed of the same conductive material as the low-potential coil 22 and the like. That is, preferably, like the low-potential coil 22 and the like, the high-potential connection wiring 81 and the pad plug electrodes 82 each include a barrier layer and a body layer.

The high-potential connection wiring 81 is formed in the same interlayer insulation layer 57 as the high-potential coil 23, in the second inner region 67 in the high-potential coil 23. The high-potential connection wiring 81 is formed as an island, and faces the high-potential terminal 12 (first high-potential terminal 12A) in the normal direction Z. The high-potential connection wiring 81 is electrically connected to the second inner end 27 of the high-potential coil 23. The high-potential connection wiring 81 is formed at an interval from the low-potential connection wiring 72 as seen in a plan view, and does not face the low-potential connection wiring 72 in the normal direction Z. This results in an increased insulation distance between the low- and high-potential connection wirings 72 and 81 and hence an increased dielectric strength voltage in the insulation layer 51.

The plurality of pad plug electrodes 82 are formed in the top insulation layer 56, in a region between the high-potential terminal 12 (first high-potential terminal 12A) and the high-potential connection wiring 81, and are electrically connected to the high-potential terminal 12 and to the high-potential connection wiring 81. The plurality of pad plug electrodes 82 each have a plane area smaller than the plane area of the high-potential connection wiring 81 as seen in a plan view.

Referring to FIG. 16, the plurality of second high-potential wirings 34 are connected respectively to the corresponding high-potential terminals 12E and 12F and to the second outer ends 28 of the corresponding transformers 21A to 21D (high-potential coils 23). The plurality of second high-potential wirings 34 have similar structures. In the following description, the structure of the second high-potential wiring 34 connected to the fifth high-potential terminal 12E and to the first transformer 21A (second transformer 21B) will be described as an example. No description will be given of the structures of the other second high-potential wirings 34, to which the description of the structure of the second high-potential wiring 34 connected to the first transformer 21A (second transformer 21B) is to be taken to apply.

Like the first high-potential wiring 33, the second high-potential wiring 34 includes a high-potential connection wiring 81 and a pad plug electrode 82. The second high-potential wiring 34 has a similar structure to the first high-potential wiring 33 except that the high-potential connection wiring 81 is connected to the second outer end 28 of the first transformer 21A (high-potential coil 23) and to the second outer end 28 of the second transformer 21B (high-potential coil 23).

The high-potential connection wiring 81 of the second high-potential wiring 34 is formed around the high-potential coil 23 in the same interlayer insulation layer 57 as the high-potential coil 23. The high-potential connection wiring 81 is formed in a region between two high-potential coils 23 adjacent to each other as seen in a plan view, and faces the high-potential terminal 12 (fifth high-potential terminal 12E) in the normal direction Z. The high-potential connection wiring 81 is formed at an interval from the low-potential connection wiring 72 as seen in a plan view, and faces the low-potential connection wiring 72 in the normal direction Z.

The plurality of pad plug electrodes 82 are formed in the top insulation layer 56, in a region between the high-potential terminal 12 (fifth high-potential terminal 12E) and the high-potential connection wiring 81, and are electrically connected to the high-potential terminal 12 and to the low-potential connection wiring 81.

Referring to FIGS. 15 and 16, preferably, the distance D1 between the low- and high-potential terminals 11 and 12 is larger than the distance D2 between the low- and high-potential coils 22 and 23 (D2<D1). Preferably, the distance D1 is larger than the total thickness DT of the plurality of interlayer insulation layers 57 (DT<D1). The ratio D2/D1 of the distance D2 to the distance D1 can be 0.01 or more but 0.1 or less. Preferably, the distance D1 is 100 μm or more but 500 μm or less. The distance D2 can be 1 μm or more but 50 μm or less. Preferably, the distance D2 is 5 μm or more but 25 μm or less. The distances D1 and D2 can have any values, which are adjusted appropriately according to the desired dielectric strength voltage.

Referring to FIGS. 14 to 19, the semiconductor device 5 has a dummy pattern 85 that is embedded in the insulation layer 51 so as to be located around the transformers 21A to 21D as seen in a plan view. In FIGS. 17 to 19, the dummy pattern 85 is indicated by hatching. The dummy pattern 85 includes a conductive member. Preferably, the dummy pattern 85 is formed of the same conductive material as the low-potential coil 22 and the like. That is, preferably, like the low-potential coil 22 and the like, the dummy pattern 85 includes a barrier layer and a body layer.

The dummy pattern 85 is formed in a pattern different (discontinuous) from that of either of the high- and low-potential coils 23 and 22, and is independent of the transformers 21A to 21D. That is, the dummy pattern 85 does not function as part of the transformers 21A to 21D. The dummy pattern 85 is formed as a shield conductor layer that shields electric fields between the low- and high-potential coils 22 and 23 in the transformers 21A to 21D to suppress electric field concentration on the high-potential coil 23.

In the embodiment, the dummy pattern 85 is patterned in dense lines so as to partly cover and partly expose a region around one or a plurality of high-potential coils 23 as seen in a plan view In the embodiment, the dummy pattern 85 is patterned at a line density per unit area that is equal to the line density of the high-potential coil 23. The line density of the dummy pattern 85 being equal to the line density of the high-potential coil 23 means that the line density of the dummy pattern 85 falls within the range of ±20% of the line density of the high-potential coil 23.

Preferably, the dummy pattern 85 is formed in a region closer to the high-potential coil 23 than to the low-potential terminal 11 as seen in a plan view. The dummy pattern 85 being closer to the high-potential coil 23 as seen in a plan view means that the distance between the dummy pattern 85 and the high-potential coil 23 is smaller than the distance between the dummy pattern 85 and the low-potential terminal 11.

The dummy pattern 85 can be formed at any depth in the insulation layer 51, which is adjusted according to the electric field strength to be attenuated. Preferably, the dummy pattern 85 is formed in a region closer to the high-potential coil 23 than to the low-potential coil 22 with respect to the normal direction Z. The dummy pattern 85 being closer to the high-potential coil 23 with respect to the normal direction Z means that, with respect to the normal direction Z, the distance between the dummy pattern 85 and the high-potential coil 23 is smaller than the distance between the dummy pattern 85 and the low-potential coil 22.

In that way, electric field concentration on the high-potential coil 23 can be suppressed properly. The smaller the distance between the dummy pattern 85 and the high-potential coil 23 with respect to the normal direction Z, the more effectively electric field concentration on the high-potential coil 23 can be suppressed. Preferably, the dummy pattern 85 is formed in the same interlayer insulation layer 57 as the high-potential coil 23. In that way, electric field concentration on the high-potential coil 23 can be suppressed more properly.

Preferably, the dummy pattern 85 is formed around, so as to be interposed in regions between, the plurality of high-potential coils 23 adjacent to each other as seen in a plan view. This makes it possible to use the regions between the plurality of high-potential coils 23 adjacent to each other to suppress undesirable electric field concentration on the plurality of high-potential coils 23.

Preferably, the dummy pattern 85 is formed so as to be interposed in a region between the low-potential terminal 11 and the high-potential coil 23 as seen in a plan view. This makes it possible to suppress undesirable conduction between the low-potential terminal 11 and the high-potential coil 23 ascribable to electric field concentration on the high-potential coil 23. Preferably, the dummy pattern 85 is interposed in a region between the low- and high-potential terminals 11 and 12 as seen in a plan view. This makes it possible to suppress undesirable conduction between the low- and high-potential terminals 11 and 12 ascribable to electric field concentration on the high-potential coil 23.

In this embodiment, the dummy pattern 85 is formed along the plurality of high-potential coils 23 as seen in a plan view and is interposed in regions between the plurality of high-potential coils 23 adjacent to each other. Moreover, the dummy pattern 85 surrounds a region that altogether includes the plurality of high-potential coils 23 and the plurality of high-potential terminals 12 as seen in a plan view. Moreover, the dummy pattern 85 is interposed in a region between the plurality of low-potential terminals 11A to 11F and the plurality of high-potential coils 23 as seen in a plan view. Moreover, the dummy pattern 85 is interposed in a region between the plurality of low-potential terminals 11A to 11F and the high-potential terminals 12A to 12F as seen in a plan view.

Referring to FIGS. 14 to 19, the dummy pattern 85 includes a plurality of dummy patterns that are in varying electrical states. The dummy pattern 85 includes a high-potential dummy pattern 86. The high-potential dummy pattern 86 is formed in the insulation layer 51 so as to be located around the transformers 21A to 21D. The high-potential dummy pattern 86 is formed in a pattern different (discontinuous) from that of either of the high- and low-potential coils 23 and 22, and is independent of the transformers 21A to 21D. That is, the high-potential dummy pattern 86 does not function as part of the transformers 21A to 21D.

In this embodiment, the high-potential dummy pattern 86 is patterned in dense lines so as to partly cover and partly expose a region around the high-potential coil 23 as seen in a plan view. In the embodiment, the high-potential dummy pattern 86 is patterned at a line density per unit area that is equal to the line density of the high-potential coil 23. The line density of the high-potential dummy pattern 86 being equal to the line density of the high-potential coil 23 means that the line density of the high-potential dummy pattern 86 falls within the range of ±20% of the line density of the high-potential coil 23.

The high-potential dummy pattern 86 shields the electric field between the low- and high-potential coils 22 and 23 in the transformers 21A to 21D to suppress electric field concentration on the high-potential coil 23. Specifically, the high-potential dummy pattern 86, by shielding the electric field between the low- and high-potential coils 22 and 23, keeps the electric field that leaks above the high-potential coil 23 away from the high-potential coil 23. This suppresses electric field concentration on the high-potential coil 23 ascribable to the electric field that leaks above the high-potential coil 23.

The high-potential dummy pattern 86 is fed with a voltage higher than the voltage fed to the low-potential coil 22. This helps suppress a voltage drop between the high-potential coil 23 and the high-potential dummy pattern 86, and thus helps suppress electric field concentration on the high-potential coil 23. Preferably, the high-potential dummy pattern 86 is fed with that voltage that is fed to the high-potential coil 23. That is, preferably, the high-potential dummy pattern 86 is fixed at an equal potential with the high-potential coil 23. This helps reliably suppress a voltage drop between the high-potential coil 23 and the high-potential dummy pattern 86, and thus helps properly suppress electric field concentration on the high-potential coil 23.

The high-potential dummy pattern 86 can be formed at any depth in the insulation layer 51, which is adjusted according to the electric field strength to be attenuated. Preferably, the high-potential dummy pattern 86 is formed in a region closer to the high-potential coil 23 than to the low-potential coil 22 with respect to the normal direction Z. The high-potential dummy pattern 86 being closer to the high-potential coil 23 with respect to the normal direction Z means that, with respect to the normal direction Z, the distance between the high-potential dummy pattern 86 and the high-potential coil 23 is smaller than the distance between the high-potential dummy pattern 86 and the low-potential coil 22.

In that way, it is possible to properly suppress electric field concentration on the high-potential coil 23. The smaller the distance between the high-potential dummy pattern 86 and the high-potential coil 23 with respect to the normal direction Z, the more effectively it is possible to suppress electric field concentration on the high-potential coil 23. Preferably, the high-potential dummy pattern 86 is formed in the same interlayer insulation layer 57 as the high-potential coil 23. In that way, it is possible to more properly suppress electric field concentration on the high-potential coil 23.

Preferably, the high-potential dummy pattern 86 is formed in a region closer to the high-potential coil 23 than to the low-potential terminal 11 as seen in a plan view. The high-potential dummy pattern 86 being closer to the high-potential coil 23 as seen in a plan view means that the distance between the high-potential dummy pattern 86 and the high-potential coil 23 is smaller than the distance between the high-potential dummy pattern 86 and the low-potential terminal 11.

Preferably, the high-potential dummy pattern 86 is formed around, so as to be interposed in regions between, the plurality of high-potential coils 23 adjacent to each other as seen in a plan view. In this way, it is possible to use the regions between the plurality of high-potential coils 23 adjacent to each other to suppress undesirable electric field concentration on the plurality of high-potential coils 23.

Preferably, the high-potential dummy pattern 86 is interposed in a region between the low-potential terminal 11 and the high-potential coil 23 as seen in a plan view. In this way, it is possible to suppress undesirable conduction between the low-potential terminal 11 and the high-potential coil 23 ascribable to electric field concentration on the high-potential coil 23. Preferably, the high-potential dummy pattern 86 is interposed in a region between the low- and high-potential terminals 11 and 12 as seen in a plan view. In this way, it is possible to suppress undesirable conduction between the low- and high-potential terminals 11 and 12 ascribable to electric field concentration on the high-potential coil 23.

In this embodiment, the high-potential dummy pattern 86 is formed along the plurality of high-potential coils 23 as seen in a plan view and is interposed in regions between the plurality of high-potential coils 23 adjacent to each other. Moreover, the high-potential dummy pattern 86 surrounds a region that altogether includes the plurality of high-potential coils 23 and the plurality of high-potential terminals 12 as seen in a plan view. Moreover, the high-potential dummy pattern 86 is interposed in a region between the plurality of low-potential terminals 11A to 11F and the plurality of high-potential coils 23 as seen in a plan view. Moreover, the high-potential dummy pattern 86 is interposed in a region between the plurality of low-potential terminals 11A to 11F and the high-potential terminals 12A to 12F.

The high-potential dummy pattern 86 is patterned, in regions between the plurality of high-potential coils 23 adjacent to each other as seen in a plan view, around the high-potential terminals 12E and 12F so as to expose regions right below the high-potential terminals 12E and 12F. Parts of the high-potential dummy pattern 86 may face the high-potential terminals 12A to 12F in the normal direction Z. Then, like the high-potential dummy pattern 86, the high-potential terminals 12E and 12F shield the electric field and thereby suppresses the electric field that leaks above the high-potential coil 23. That is, the high-potential terminals 12E and 12F are formed as a shield conductor layer that together with the high-potential dummy pattern 86 suppresses electric field concentration on the high-potential coil 23.

Preferably, the high-potential dummy pattern 86 is formed so as to have ends. This helps prevent formation of a current loop circuit (closed circuit) in the high-potential dummy pattern 86, and thus helps suppress noise ascribable to a current in the high-potential dummy pattern 86. It is thus possible to suppress undesirable electric field concentration ascribable to noise, and also to suppress variation of the electrical characteristics of the transformers 21A to 21D.

Specifically, the high-potential dummy pattern 86 includes a first high-potential dummy pattern 87 and a second high-potential dummy pattern 88. The first high-potential dummy pattern 87 is formed in regions between the plurality of transformers 21A to 21D (the plurality of high-potential coils 23) adjacent to each other as seen in a plan view. The second high-potential dummy pattern 88 is formed in a region outside the regions between the plurality of transformers 21A to 21D (the plurality of high-potential coils 23) adjacent to each other as seen in a plan view.

In the following description, the region between the first transformer 21A (high-potential coil 23) and the second transformer 21B (high-potential coil 23), which are adjacent to each other, will be referred to as the first region 89; likewise, the region between the second transformer 21B (high-potential coil 23) and the third transformer 21C (high-potential coil 23) will be referred to as the second region 90; and the region between the third transformer 21C (high-potential coil 23) and the fourth transformer 21D (high-potential coil 23) will be referred to as the third region 91.

In the embodiment, the first high-potential dummy pattern 87 is electrically connected via the first high-potential wiring 33 to the high-potential terminal 12 (fifth high-potential terminal 12E). Specifically, the first high-potential dummy pattern 87 includes a first connection part 92 connected to the first high-potential wiring 33. The first connection part 92 can be located anywhere. Thus, the first high-potential dummy pattern 87 is fixed at an equal potential with the plurality of high-potential coils 23.

Specifically, the first high-potential dummy pattern 87 includes a first pattern 93 formed in the first region 89, a second pattern 94 formed in the second region 90, and a third pattern 95 formed in the third region 91. Thus, in the first, second, and third regions 89, 90, and 91, the first high-potential dummy pattern 87 suppresses the electric field that leaks above the high-potential coil 23 and thereby suppresses electric field concentration on the high-potential coil 23.

In the embodiment, the first, second, and third patterns 93, 94, and 95 are formed integrally and are fixed at an equal potential. So long as the first, second, and third patterns 93, 94, and 95 are fixed at an equal potential, they may be formed separate from each other.

Referring to FIGS. 14 and 17, the first pattern 93 is connected via the first connection part 92 to the first high-potential wiring 33. The first pattern 93 is patterned in dense lines so as to cover part of the first region 89 as seen in a plan view. The first pattern 93 is formed in the first region 89 at an interval from the high-potential terminal 12 (fifth high-potential terminal 12E) as seen in a plan view, and does not face the high-potential terminal 12 in the normal direction Z. The first pattern 93 is formed at an interval from the low-potential connection wiring 72 as seen in a plan view, and does not face the low-potential connection wiring 72 in the normal direction Z. This results in an increased insulation distance between the first pattern 93 and the low-potential connection wiring 72 and hence an increased dielectric strength voltage in the insulation layer 51.

The first pattern 93 includes a first peripheral line 96, a second peripheral line 97, and a plurality of first middle lines 98. The first peripheral line 96 extends in a strip shape along the circumference of the high-potential coil 23 of the first transformer 21A. In the embodiment, the first peripheral line 96 is formed in a ring shape to have open ends in the first region 89 as seen in a plan view. The width of the open ends of the first peripheral line 96 is smaller than the width of the high-potential coil 23 along the second direction Y.

The first peripheral line 96 can have a width of 0.1 μm or more but 5 μm or less. Preferably, the first peripheral line 96 has a width of 1 μm or more but 3 μm or less. The width of the first peripheral line 96 is defined by its width in the direction orthogonal to the direction in which the first peripheral line 96 extends. Preferably, the width of the first peripheral line 96 is equal to the width of the high-potential coil 23. The width of the first peripheral line 96 being equal to the width of the high-potential coil 23 means that the width of the first peripheral line 96 falls within the range of ±20% of the width of the high-potential coil 23.

The first pitch between the first peripheral line 96 and the high-potential coil 23 (first transformer 21A) can be 0.1 μm or more but 5 μm or less. Preferably, the first pitch is 1 μm or more but 3 μm or less. Preferably, the first pitch is equal to the second winding pitch of the high-potential coil 23. The first pitch being equal to the first winding pitch means that the first pitch falls within the range of ±20% of the first winding pitch.

The second peripheral line 97 extends in a strip shape along the circumference of the high-potential coil 23 of the second transformer 21B. In the embodiment, the second peripheral line 97 is formed in a ring shape with open ends in the first region 89 as seen in a plan view. The width of the open ends of the second peripheral line 97 is smaller than the width of the high-potential coil 23 along the second direction Y. The open ends of the second peripheral line 97 faces the open ends of the first peripheral line 96 along the first direction X.

The second peripheral line 97 can have a width of 0.1 μm or more but 5 μm or less. Preferably, the second peripheral line 97 has a width of 1 μm or more but 3 μm or less. The width of the second peripheral line 97 is defined by its width in the direction orthogonal to the direction in which the second peripheral line 97 extends. Preferably, the width of the second peripheral line 97 is equal to the width of the high-potential coil 23. The width of the second peripheral line 97 being equal to the width of the high-potential coil 23 means that the width of the second peripheral line 97 falls within the range of ±20% of the width of the high-potential coil 23.

The second pitch between the second peripheral line 97 and the high-potential coil 23 (second transformer 21B) can be 0.1 μm or more but 5 μm or less. Preferably, the second pitch is 1 μm or more but 3 μm or less. Preferably, the second pitch is equal to the second winding pitch of the high-potential coil 23. The second pitch being equal to the second winding pitch means that the second pitch falls within the range of ±20% of the second winding pitch.

The plurality of first middle lines 98 extend each in a strip shape in the first region 89, in a region between the first and second peripheral lines 96 and 97. The plurality of first middle lines 98 include at least one (in the embodiment, one) first connection line 99 that electrically connects together the first and second peripheral lines 96 and 97.

To prevent formation of a current loop circuit, preferably, the plurality of first middle lines 98 include only one first connection line 99. The first connection line 99 can be located anywhere. At least one of the plurality of first middle lines 98 has formed in it a slit 100 for cutting off a current loop circuit. The location of the slit 100 is adjusted to suit the design of the plurality of first middle lines 98.

Preferably, the plurality of first middle lines 98 are formed each in a strip shape extending in the direction in which the plurality of high-potential coil 23 face each other. In the embodiment, the plurality of first middle lines 98 are formed each in a strip shape extending in the first direction X, and are formed at intervals from each other in the second direction Y. The plurality of first middle line 98 are, as a whole, formed in the shape of stripes extending in the first direction X as seen in a plan view.

Specifically, the plurality of first middle lines 98 include a plurality of first branch portions 101 and a plurality of second branch portions 102. The plurality of first branch portions 101 are laid in the shape of stripes from the first peripheral line 96 toward the second peripheral line 97. The tip parts of the plurality of first branch portions 101 are formed at an interval from the first peripheral line 96 on the second peripheral line 97 side.

The plurality of second branch portions 102 are laid in the shape of stripes from the second peripheral line 97 toward the first peripheral line 96. The tip parts of the plurality of second branch portions 102 are formed at an interval from the second peripheral line 97 on the first peripheral line 96 side. In the embodiment, the plurality of second branch portions 102 are formed such that two of them lie on opposite sides of one first branch portion 101, alternately with the plurality of first branch portions 101 at intervals from one another in the second direction Y.

The plurality of second branch portions 102 may be laid such that two of them lie on opposite sides of a plurality of first branch portions 101, or such that a group of a plurality of second branch portions 102 lies adjacent to a group of a plurality of first branch portions 101. The slit 100, the plurality of first branch portions 101, and the plurality of second branch portions 102 prevent formation of a current loop circuit in the first pattern 93.

The first middle line 98 may have a width of 0.1 μm or more but 5 μm or less with respect to the second direction Y. Preferably, the first middle line 98 has a width of 1 μm or more but 3 μm or less. Preferably, the width of the first middle line 98 is equal to the width of the high-potential coil 23. The width of the first middle line 98 being equal to the width of the high-potential coil 23 means that the width of the first middle line 98 falls within the range of ±20% of the width of the high-potential coil 23.

The third pitch between two adjacent first middle lines 98 can be 0.1 μm or more but 5 μm or less. Preferably, the third pitch is 1 μm or more but 3 μm or less. The third pitch is defined by the distance between a plurality of adjacent first middle lines 98 with respect to the second direction Y. Preferably, the third pitch is equal everywhere. The third pitch being equal everywhere means that any individual third pitch falls within the range of ±20% of the third pitch. Preferably, the third pitch is equal to the second winding pitch of the high-potential coil 23. The third pitch being equal to the second winding pitch means that the third pitch falls with the range of ±20% of the second winding pitch.

Referring to FIGS. 14 and 18, the second pattern 94 is electrically connected via the first high-potential wiring 33 to the high-potential terminal 12. In the embodiment, the second pattern 94 is electrically connected via the second peripheral line 97 of the first pattern 93 to the first high-potential wiring 33 (fifth high-potential terminal 12E). The second pattern 94 is patterned in dense lines so as to cover the second region 90.

The second pattern 94 includes the second peripheral line 97, mentioned above, a third peripheral line 103, and a plurality of second middle lines 104. The third peripheral line 103 extends in a strip shape along the circumference of the high-potential coil 23 of the third transformer 21C. In the embodiment, the third peripheral line 103 is formed in a ring shape to have open ends in the third region 91 as seen in a plan view. The width of the open ends of the third peripheral line 103 is smaller than the width of the high-potential coil 23 of the third transformer 21C along the second direction Y.

The third peripheral line 103 can have a width of 0.1 μm or more but 5 μm or less. Preferably, the third peripheral line 103 has a width of 1 μm or more but 3 μm or less. The width of the third peripheral line 103 is defined by its width in the direction orthogonal to the direction in which the third peripheral line 103 extends. Preferably, the width of the third peripheral line 103 is equal to the width of the high-potential coil 23. The width of the third peripheral line 103 being equal to the width of the high-potential coil 23 means that the width of the third peripheral line 103 falls within the range of ±20% of the width of the high-potential coil 23.

The fourth pitch between the third peripheral line 103 and the high-potential coil 23 (third transformer 21C) can be 0.1 μm or more but 5 μm or less. Preferably, the fourth pitch is 1 μm or more but 3 μm or less. Preferably, the fourth pitch is equal to the second winding pitch of the high-potential coil 23. The fourth pitch being equal to the second winding pitch means that the fourth pitch falls within the rage of ±20% of the second winding pitch.

The plurality of second middle lines 104 extend each in a strip shape in the second region 90, in a region between the second and third peripheral lines 97 and 103. The plurality of second middle lines 104 include at least one (in the embodiment, one) second connection line 105 that connect together the second and third peripheral lines 97 and 103.

To prevent formation of a current loop circuit, preferably, the plurality of second middle lines 104 include only one second connection line 105. The second connection line 105 may have a width larger than the width of the other second middle lines 104. The second connection line 105 can be located anywhere. At least one of the plurality of second middle lines 104 has formed in it a slit 106 for cutting off a current loop circuit. The position of the slit 106 is adjusted to suit the design of the plurality of second middle lines 104.

Preferably, the plurality of second middle lines 104 are formed each in a strip shape extending in the direction in which the plurality of high-potential coils 23 face each other. In the embodiment, the plurality of second middle lines 104 are formed each in a strip shape extending in the first direction X, at intervals from each other in the second direction Y. The plurality of second middle lines 104 are, as a whole, formed in the shape of stripes extending in the first direction X as seen in a plan view.

Specifically, the plurality of second middle lines 104 include a plurality of third branch portions 107 and a plurality of fourth branch portions 108. The plurality of third branch portions 107 are laid in the shape of stripes from the second peripheral line 97 toward the third peripheral line 103. The tip parts of the plurality of third branch portions 107 are formed at an interval from the third peripheral line 103 on the second peripheral line 97 side.

The plurality of fourth branch portions 108 are laid in the shape of stripes from the third peripheral line 103 toward the second peripheral line 97. The tip parts of the plurality of fourth branch portions 108 are formed at an interval from the second peripheral line 97 on the third peripheral line 103 side. In the embodiment, the plurality of fourth branch portions 108 are formed such that two of them lie on opposite sides of one third branch portion 107, alternately with the plurality of third branch portions 107 at intervals from one another in the second direction Y.

The plurality of fourth branch portions 108 may be laid such that two of them lie on opposite sides of a plurality of third branch portions 107, or such that a group of a plurality of fourth branch portions 108 lies adjacent to a group of a plurality of third branch portions 107. The slit 106, the plurality of third branch portions 107, and the plurality of fourth branch portions 108 prevent formation of a current loop circuit in the second pattern 94.

The second middle lines 104 can have a width of 0.1 μm or more but 5 μm or less with respect to the second direction Y. Preferably, the second middle lines 104 have a width of 1 μm or more but 3 μm or less. Preferably, the width of the second middle lines 104 is equal to the width of the high-potential coil 23. The width of the second middle lines 104 being equal to the width of the high-potential coil 23 means that the width of the second middle lines 104 falls within the range of ±20% of the width of the high-potential coil 23.

The fifth pitch between two adjacent second middle lines 104 can be 0.1 μm or more but 5 μm or less. Preferably, the fifth pitch is 1 μm or more but 3 μm or less. The fifth pitch is defined by the distance between a plurality of adjacent second middle lines 104 with respect to the second direction Y. Preferably, the fifth pitch is equal everywhere. The fifth pitch being equal everywhere means that any individual fifth pitch falls within the range of ±20% of the fifth pitch. Preferably, the fifth pitch is equal to the second winding pitch of the high-potential coil 23. The fifth pitch being equal to the second winding pitch means that the fifth pitch falls within the range of ±20% of the second winding pitch.

Referring to FIGS. 14 and 19, the third pattern 95 is electrically connected to the first high-potential wiring 33. In the embodiment, the third pattern 95 is electrically connected via the second and first patterns 94 and 93 to the first high-potential wiring 33. The third pattern 95 is patterned in dense lines so as to cover part of the third region 91. The third pattern 95 is formed in the third region 91, at an interval from the high-potential terminal 12 (sixth high-potential terminal 12F) as seen in a plan view, and does not face the high-potential terminal 12 in the normal direction Z.

The third pattern 95 is formed at an interval from the low-potential connection wiring 72 as seen in a plan view, and does not face the low-potential connection wiring 72 in the normal direction Z. This results in an increased insulation distance between the third pattern 95 and the low-potential connection wiring 72 with respect to the normal direction Z and hence an increased dielectric strength voltage in the insulation layer 51.

The third pattern 95 includes the third peripheral line 103, mentioned above, a fourth peripheral line 109, and a plurality of third middle lines 110. The fourth peripheral line 109 extends in a strip shape along the circumference of the high-potential coil 23 of the fourth transformer 21D. In the embodiment, the fourth peripheral line 109 is formed in a ring shape to have open ends in the third region 91 as seen in a plan view. The width of the open ends of the fourth peripheral line 109 is smaller than the width of the high-potential coil 23 of the fourth transformer 21D along the second direction Y. The open ends of the fourth peripheral line 109 faces the open ends of the third peripheral line 103 along the first direction X.

The fourth peripheral line 109 can have a width of 0.1 μm or more but 5 μm or less. Preferably, the fourth peripheral line 109 has a width of 1 μm or more but 3 μm or less. The width of the fourth peripheral line 109 is defined by its width in the direction orthogonal to the direction in which the fourth peripheral line 109 extends. Preferably, the width of the fourth peripheral line 109 is equal to the width of the high-potential coil 23. The width of the fourth peripheral line 109 being equal to the width of the high-potential coil 23 means that the width of the fourth peripheral line 109 falls within the range of ±20% of the width of the high-potential coil 23.

The sixth pitch between the fourth peripheral line 109 and the high-potential coil 23 (fourth transformer 21D) can be 0.1 μm or more but 5 μm or less. Preferably, the sixth pitch is 1 μm or more but 3 μm or less. Preferably, the sixth pitch is equal to the second winding pitch of the high-potential coil 23. The sixth pitch being equal to the second winding pitch means that the sixth pitch falls within the range of ±20% of the second winding pitch.

The plurality of third middle lines 110 extend each in a strip shape in the third region 91, in a region between the third and fourth peripheral lines 103 and 109. The plurality of third middle lines 110 include at least one (in the embodiment, one) third connection line 111 that connects together the third and fourth peripheral lines 103 and 109.

To prevent formation of a current loop circuit, preferably, the plurality of third middle lines 110 include only one third connection line 111. The third connection line 111 can be located anywhere. At least one of the plurality of third middle lines 110 has formed in it a slit 112 for cutting off a current loop circuit. The position of the slit 112 is adjusted to suit the design of the plurality of third middle lines 110.

Preferably, the plurality of third middle lines 110 are formed each in a strip shape extending in the direction in which the plurality of high-potential coil 23 face each other. In the embodiment, the plurality of third middle lines 110 are formed each in a strip shape extending in the first direction X, and are formed at intervals from each other in the second direction Y. The plurality of third middle lines 110 are, as a whole, formed in the shape of stripes as seen in a plan view.

In the embodiment, the plurality of third middle lines 110 include a plurality of fifth branch portions 113 and a plurality of sixth branch portions 114. The plurality of fifth branch portions 113 are laid in the shape of stripes from the third peripheral line 103 toward the fourth peripheral line 109. The tip parts of the plurality of fifth branch portions 113 are formed at an interval from the first peripheral line 109 on the third peripheral line 103 side.

The plurality of sixth branch portions 114 are laid in the shape of stripes from the fourth peripheral line 109 toward the third peripheral line 103. The tip parts of the plurality of sixth branch portions 114 are formed at an interval from the third peripheral line 103 on the fourth peripheral line 109 side. In the embodiment, the plurality of sixth branch portions 114 are formed such that two of them lie on opposite sides of one fifth branch portion 113, alternately with the plurality of fifth branch portions 113 at intervals from one another in the second direction Y.

The plurality of sixth branch portions 114 may be laid such that two of them lie on opposite sides of a plurality of fifth branch portions 113, or such that a group of a plurality of sixth branch portions 114 lies adjacent to a group of a plurality of fifth branch portions 113. The slit 112, the plurality of fifth branch portions 113, and the plurality of sixth branch portions 114 prevent formation of a current loop circuit in the third pattern 95.

The third middle lines 110 can have a width of 0.1 μm or more but 5 μm or less with respect to the second direction Y. Preferably, the third middle lines 110 have a width of 1 μm or more but 3 μm or less. Preferably, the width of the third middle lines 110 is equal to the width of the high-potential coil 23. The width of the third middle lines 110 being equal to the width of the high-potential coil 23 means that the width of the third middle lines 110 falls within the range of ±20% of the width of the high-potential coil 23.

The seventh pitch between two adjacent third middle lines 110 can be 0.1 μm or more but 5 μm or less. Preferably, the seventh pitch is 1 μm or more but 3 μm or less. The seventh pitch is defined by the distance between a plurality of adjacent third middle lines 110 with respect to the second direction Y. Preferably, the seventh pitch is equal everywhere. The seventh pitch being equal everywhere means that any individual seventh pitch falls within the range of ±20% of the seventh pitch. Preferably, the seventh pitch is equal to the second winding pitch of the high-potential coil 23. The seventh pitch being equal to the second winding pitch means that the seventh pitch falls within the range of ±20% of the second winding pitch.

Referring to FIGS. 14 to 19, in the embodiment, the second high-potential dummy pattern 88 is electrically connected via the first high-potential dummy pattern 87 to the high-potential terminal 12. Specifically, the second high-potential dummy pattern 83 includes a second connection part 115 connected to the first high-potential dummy pattern 87. The second connection part 115 can be located anywhere. Thus, the second high-potential dummy pattern 88 is fixed at an equal potential with the plurality of high-potential coils 23.

In a region outside the first, second, and third regions 89, 90, and 91, the second high-potential dummy pattern 88 suppresses the electric field that leaks above the high-potential coil 23 and suppresses electric field concentration on the plurality of high-potential coils 23. In the embodiment, the second high-potential dummy pattern 88 surrounds a region that altogether includes the plurality of high-potential coils 23 and the plurality of high-potential terminals 12A to 12F as seen in a plan view. In the embodiment, the second high-potential dummy pattern 88 is formed in the shape of an elongate circular ring (elliptical ring).

Thus, the second high-potential dummy pattern 88 is interposed in regions between the plurality of low-potential terminals 11A to 11F and the plurality of high-potential coils 23 as seen in a plan view. The second high-potential dummy pattern 88 is interposed also in regions between the plurality of low-potential terminals 11A to 11F and the plurality of high-potential terminals 12A to 12F as seen in a plan view

The second high-potential dummy pattern 88 includes a plurality of (in the embodiment, six) high-potential lines 116A, 116B, 116C, 116D, 116E, and 116F. The number of high-potential lines is adjusted according to the electric field to be attenuated. The plurality of high-potential lines 116A to 116F are formed in this order at intervals from each other in the direction away from the plurality of high-potential coil 23.

The plurality of high-potential lines 116A to 116F surround the plurality of high-potential coils 23 altogether as seen in a plan view. Specifically, the plurality of high-potential lines 116A to 116F surrounds a region that altogether includes the plurality of high-potential coils 23 and the plurality of high-potential terminals 12A to 12F as seen in a plan view. In the embodiment, the plurality of high-potential lines 116A to 116F are formed in the shape of an elongate circular ring (elliptical ring).

The plurality of high-potential lines 116A to 116F each include a slit 117 for cutting off a current loop circuit. The location of the slit 117 is adjusted to suit the design of the plurality of high-potential lines 116A to 116F.

The high-potential lines 116A to 116F can have a width of 0.1 μm or more but 5 μm or less. Preferably, the high-potential lines 116A to 116F have a width of 1 μm or more but 3 μm or less. The width of the high-potential lines 116A to 116F is defined by their width in the direction orthogonal to the direction in which the high-potential lines 116A to 116F extend. Preferably, the width of the high-potential lines 116A to 116F is equal to the width of the high-potential coil 23. The width of the high-potential lines 116A to 116F being equal to the width of the high-potential coil 23 means that the width of the high-potential lines 116A to 116F falls within the range of ±20% of the width of the high-potential coil 23.

The eighth pitch between two adjacent high-potential lines 116A to 116F can be 0.1 μm or more but 5 μm or less. Preferably, the eighth pitch is 1 μm or more but 3 μm or less. Preferably, the eighth pitch is equal everywhere. The eighth pitch being equal everywhere means that any individual eighth pitch falls with the range of ±20% of the eighth pitch.

The ninth pitch between the first and second high-potential dummy patterns 87 and 88, which are adjacent to each other, can be 0.1 μm or more but 5 μm or less. Preferably, the ninth pitch is 1 μm or more but 3 μm or less. Preferably, the ninth pitch is equal to the second winding pitch of the high-potential coil 23. The ninth pitch being equal to the second winding pitch means that the ninth pitch falls with the range of ±20% of the second winding pitch. The plurality of high-potential lines 116A to 116F can include any number of them with any width, pitch, etc., which are adjusted according to the electric field to be attenuated.

Referring to FIGS. 14 to 19, the dummy pattern 85 includes a floating dummy pattern 121 that is formed in an electrically floating state in the insulation layer 51 so as to be located around the transformers 21A to 21D as seen in a plan view. The floating dummy pattern 121 is formed in a pattern different (discontinuous) from that of either of the high- and low-potential coils 23 and 22, and is independent of the transformers 21A to 21D. That is, the floating dummy pattern 121 does not function as part of the transformers 21A to 21D.

In the embodiment, the floating dummy pattern 121 is patterned in dense lines so as to partly cover and partly expose a region around the high-potential coil 23 as seen in a plan view. The floating dummy pattern 121 can be formed so as to have ends or no ends.

The floating dummy pattern 121 is patterned at a line density per unit area that is equal to the line density of the high-potential coil 23. The line density of the floating dummy pattern 121 being equal to the line density of the high-potential coil 23 means that the line density of the floating dummy pattern 121 falls within the range of ±20% of the line density of the high-potential coil 23.

The floating dummy pattern 121 is patterned at a line density per unit area that is equal to the line density of the high-potential dummy pattern 86. The line density of the floating dummy pattern 121 being equal to the line density of the high-potential dummy pattern 86 means that the line density of the floating dummy pattern 121 falls within the range of ±20% of the line density of the high-potential dummy pattern 86.

The floating dummy pattern 121 shields the electric field between the low- and high-potential coils 22 and 23 in the transformers 21A to 21D, and suppresses electric field concentration on the high-potential coil 23. Specifically, the floating dummy pattern 121 diverts the electric field that leaks above the high-potential coil 23 into a direction away from the high-potential coil 23. It is thus possible to suppress electric field concentration on the high-potential coil 23.

The floating dummy pattern 121 also diverts the electric field that leaks above the high-potential dummy pattern 86 around it into a direction away from the high-potential coil 23 and the high-potential dummy pattern 86. It is thus possible to suppress electric field concentration on the high-potential dummy pattern 86 and also to properly suppress electric field concentration on the high-potential coil 23.

The floating dummy pattern 121 can be formed at any depth in the insulation layer 51, which is adjusted according to the electric field strength to be attenuated. Preferably, the floating dummy pattern 121 is formed in a region closer to the high-potential coil 23 than to the low-potential coil 22 with respect to the normal direction Z. The floating dummy pattern 121 being closer to the high-potential coil 23 with respect to the normal direction Z means that, with respect to the normal direction Z, the distance between the floating dummy pattern 121 and the high-potential coil 23 is smaller than the distance between the floating dummy pattern 121 and the low-potential coil 22.

In that way, it is possible to properly suppress electric field concentration on the high-potential coil 23. The smaller the distance between the floating dummy pattern 121 and the high-potential coil 23 with respect to the normal direction Z, the more effectively it is possible to suppress electric field concentration on the high-potential coil 23. Preferably, the floating dummy pattern 121 is formed in the same interlayer insulation layer 57 as the high-potential coil 23. In that way, it is possible to more properly suppress electric field concentration on the high-potential coil 23.

Preferably, the floating dummy pattern 121 is interposed in a region between the low-potential terminal 11 and the high-potential coil 23 as seen in a plan view. In this way, it is possible to suppress undesirable conduction between the low-potential terminal 11 and the high-potential coil 23 ascribable to electric field concentration on the high-potential coil 23. Preferably, the floating dummy pattern 121 is interposed in a region between the low- and high-potential terminals 11 and 12 as seen in a plan view. In this way, it is possible to suppress undesirable conduction between the low- and high-potential terminals 11 and 12 ascribable to electric field concentration on the high-potential coil 23.

In the embodiment, the floating dummy pattern 121 is formed along a plurality of high-potential coils 23 as seen in a plan view. Specifically, the floating dummy pattern 121 surrounds a region that altogether includes a plurality of high-potential coils 23 and a plurality of high-potential terminals 12 as seen in a plan view. In the embodiment, the floating dummy pattern 121 surrounds a region that altogether includes a plurality of high-potential coils 23 and the plurality of high-potential terminals 12 with the high-potential dummy pattern 86 (second high-potential dummy pattern 88) in between as seen in a plan view.

Thus, the floating dummy pattern 121 is interposed in a region between the plurality of low-potential terminals 11A to 11F and the plurality of high-potential coils 23 as seen in a plan view. Moreover, the floating dummy pattern 121 is interposed in a region between the plurality of low-potential terminals 11A to 11F and the plurality of high-potential terminals 12A to 12F.

Any number of floating lines can be provided, which is adjusted according to the electric field strength to be attenuated. In the embodiment, the floating dummy pattern 121 includes a plurality of (in the diagrams, six) floating lines 122A, 122B, 122C, 122D, 122E, and 122F. The plurality of floating lines 122A to 122F are formed in this order at intervals from each other in a direction away from the plurality of high-potential coils 23.

The plurality of floating lines 122A to 122F surrounds the plurality of high-potential coils 23 altogether as seen in a plan view. Specifically, the plurality of floating lines 122A to 122F surrounds a region that altogether includes the plurality of high-potential coils 23 and the plurality of high-potential terminals 12A to 12F with the high-potential dummy pattern 86 in between as seen in a plan view. In the embodiment, the plurality of floating lines 122A to 122F are formed in the shape of an elongate circular ring (elliptical ring) as seen in a plan view.

The floating lines 122A to 122F can have a width of 0.1 μm or more but 5 μm or less. Preferably, the floating lines 122A to 122F have a width of 1 μm or more but 3 μm or less. The width of the floating lines 122A to 122F is defined by their width in the direction orthogonal to the direction in which the floating lines 122A to 122F extend.

The tenth pitch between two adjacent floating lines 122A to 122F can be 0.1 μm or more but 5 μm or less. Preferably, the tenth pitch is 1 μm or more but 3 μm or less. Preferably, the width of the floating lines 122A to 122F is equal to the width of the high-potential coil 23. The width of the floating lines 122A to 122F being equal to the width of the high-potential coil 23 means that the width of the floating lines 122A to 122F falls with the range of ±20% of the width of the high-potential coil 23.

The eleventh pitch between the floating dummy pattern 121 and the high-potential dummy pattern 86 (second high-potential dummy pattern 88) can be 0.1 μm or more but 5 μm or less. Preferably, the eleventh pitch is 1 μm or more but 3 μm or less. Preferably, the eleventh pitch is equal everywhere. The eleventh pitch being equal everywhere means that any individual eleventh pitch falls with the range of ±20% of the eleventh pitch.

Preferably, the eleventh pitch is equal to the second winding pitch of the high-potential coil 23. The eleventh pitch being equal to the second winding pitch means that the eleventh pitch falls with the range of ±20% of the second winding pitch. FIGS. 12 to 14 show, for the sake of clearness, an example where the eleventh pitch is larger than the second winding pitch.

Preferably, the twelfth pitch between the floating dummy pattern 121 and the high-potential dummy pattern 86 is equal to the second winding pitch. The twelfth pitch being equal to the second winding pitch means that the twelfth pitch falls with the range of ±20% of the second winding pitch. The plurality of floating lines 122A to 122F can include any number of them with any width, pitch, etc., which are adjusted according to the electric field to be attenuated.

Referring to FIGS. 15 and 16, the semiconductor device 5 includes a second functional device 60 that is formed in the first principal surface 42 of the semiconductor chip 41 in a device region 62. The second functional device 60 is formed using a superficial part of the first principal surface 42 and/or a region on the first principal surface 42 of the semiconductor chip 41, and is covered by the insulation layer 51 (bottom insulation layer 55). In FIG. 11, the second functional device 60 is shown in a simplified form by broken lines indicated in a superficial part of the first principal surface 42.

The second functional device 60 is electrically connected to a low-potential terminal 11 via a low-potential wiring, and is electrically connected to a high-potential terminal 12 via a high-potential wiring. Except that the low-potential wiring is patterned in the insulation layer 51 so as to be connected to the second functional device 60, it has a similar structure to the first low-potential wiring 31 (second low-potential wiring 32). Except that the high-potential wiring is patterned in the insulation layer 51 so as to be connected to the second functional device 60, it has a similar structure to the first high-potential wiring 33 (second high-potential wiring 34). No description will be given of the low- and high-potential wirings associated with the second functional device 60.

The second functional device 60 can include at least one of a passive device, a semiconductor rectification device, and a semiconductor switching device. The second functional device 60 can include a circuit network comprising a selective combination of any two or more of a passive device, a semiconductor rectification device, and a semiconductor switching device. The circuit network can constitute part or the whole of an integrated circuit.

The passive device can include a semiconductor passive device. The passive device can include one or both of a resistor and a capacitor. The semiconductor rectification device can include at least one of a pn-junction diode, a PIN diode, a Zener diode, a Schottky barrier diode, and a fast-recovery diode. The semiconductor switching device can include at least one of a BJT (bipolar junction transistor), a MISFET (metal-insulator-semiconductor field-effect transistor), an IGBT (insulated-gate bipolar junction transistor), and a JFET (junction field-effect transistor).

Referring to FIGS. 15 and 16, the semiconductor device 5 further includes a sealing conductor 61 embedded in the insulation layer 51. The sealing conductor 61 is embedded in the form of walls in the insulation layer 51, at intervals from the insulation side walls 53A to 53D as seen in a plan view, and partitions the insulation layer 51 into the device region 62 and an outer region 63. The sealing conductor 61 prevents moisture entry and crack development from the outer region 63 to the device region 62.

The device region 62 is a region that includes the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. The outer region 63 is a region outside the device region 62.

The sealing conductor 61 is electrically isolated from the device region 62. Specifically, the sealing conductor 61 is electrically isolated from the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. More specifically, the sealing conductor 61 is held in an electrically floating state. The sealing conductor 61 does not form a current path connected to the device region 62.

The sealing conductor 61 is formed in the shape of a stripe along the insulation side walls 53A to 53D. In the embodiment, the sealing conductor 61 is formed in a quadrangular ring shape (specifically, a rectangular ring shape) as seen in a plan view. Thus, the sealing conductor 61 defines the outer region 63 in a quadrangular ring shape (specifically, a rectangular ring shape) surrounding the device region 62 as seen in a plan view.

Specifically, the sealing conductor 61 has a top end part at the insulation principal surface 52 side, a bottom end part at the semiconductor chip 41 side, and a wall part that extends in the form of walls between the top and bottom end parts. In the embodiment, the top end part of the sealing conductor 61 is formed at an interval from the insulation principal surface 52 toward the semiconductor chip 41, and is located in the insulation layer 51. In the embodiment, the top end part of the sealing conductor 61 is covered by the top insulation layer 56. The top end part of the sealing conductor 61 can be covered by one or a plurality of interlayer insulation layers 57. The top end part of the sealing conductor 61 can be exposed through the top insulation layer 56. The bottom end part of the sealing conductor 61 is formed at an interval from the semiconductor chip 41 toward the top end part.

Thus, in the embodiment, the sealing conductor 61 is embedded in the insulation layer 51 so as to be located at the semiconductor chip 41 side of the plurality of low-potential terminals 11 and the plurality of high-potential terminals 12. Moreover, in the insulation layer 51, the sealing conductor 61 faces, in the direction parallel to the insulation principal surface 52, the first functional device 45 (plurality of transformers 21), the first low-potential wirings 31, the second low-potential wirings 32, the first high-potential wirings 33, the second high-potential wirings 34, and the dummy pattern 85. In the insulation layer 51, the sealing conductor 61 can face, in the direction parallel to the insulation principal surface 52, part of the second functional device 60.

The sealing conductor 61 includes a plurality of sealing plug conductors 64 and one or a plurality of (in the embodiment, a plurality of) sealing via conductors 65. Any number of sealing via conductors 65 may be provided. Of the plurality of sealing plug conductors 64, the top sealing plug conductor 64 constitutes the top end part of the sealing conductor 61. The plurality of sealing via conductors 65 constitute the bottom end part of the sealing conductor 61. Preferably, the sealing plug conductors 64 and the sealing via conductors 65 are formed of the same conductive material as the low-potential coil 22. That is, preferably, like the low-potential coil 22 and the like, the sealing plug conductors 64 and the sealing via conductors 65 each include a barrier layer and a body layer.

The plurality of sealing plug conductors 64 are embedded in the plurality of interlayer insulation layers 57 respectively, and are each formed in a quadrangular ring shape (specifically, a rectangular ring shape) surrounding the device region 62. The plurality of sealing plug conductors 64 are stacked together from the bottom insulation layer 55 to the top insulation layer 56 so as to be connected together. The number of layers stacked in the plurality of sealing plug conductors 64 is equal to the number of layers in the plurality of interlayer insulation layers 57. Needless to say, one or a plurality of sealing plug conductors 64 may be formed that penetrates a plurality of interlayer insulation layers 57.

So long as a set of a plurality of sealing plug conductor 64 constitutes one ring-shaped sealing conductor 61, not all the sealing plug conductors 64 need be formed in a ring shape. For example, at least one of the plurality of sealing plug conductors 64 can be formed so as to have ends. Or at least one of the plurality of sealing plug conductors 64 may be divided into a plurality of strip-shaped portions with ends. However, with consideration given to the risk of moisture entry and crack development into the device region 62, preferably, the plurality of sealing plug conductors 64 are formed so as to have no ends (in a ring shape).

The plurality of sealing via conductors 65 are formed in the bottom insulation layer 55, in a region between the semiconductor chip 41 and the sealing plug conductors 64. The plurality of sealing via conductors 65 are formed at an interval from the semiconductor chip 41, and are connected to the sealing plug conductors 64. The plurality of sealing via conductors 65 have a plane area smaller than the plane area of the sealing plug conductors 64. In a case where a single sealing via conductor 65 is formed, the single sealing via conductors 65 can have a plane area larger than the plane area of the sealing plug conductors 64.

The sealing conductor 61 can have a width of 0.1 μm or more but 10 μm or less. Preferably, the sealing conductor 61 has a width of 1 μm or more but 5 μm or less. The width of the sealing conductor 61 is defined by its width in the direction orthogonal to the direction in which it extends.

Referring to FIGS. 15, 16, and 20, the semiconductor device 5 further includes a separation structure 130 that is interposed between the semiconductor chip 41 and the sealing conductor 61 and that electrically isolates the sealing conductor 61 from the semiconductor chip 41. Preferably, the separation structure 130 includes an insulator. In the embodiment, the separation structure 130 is a field insulation film 131 formed on the first principal surface 42 of the semiconductor chip 41.

The field insulation film 131 includes at least one of an oxide film (silicon oxide film) and a nitride film (silicon nitride film). Preferably, the field insulation film 131 is a LOCOS (local oxidation of silicon) film as one example of an oxide film that is formed through oxidation of the first principal surface 42 of the semiconductor chip 41. The field insulation film 131 can have any thickness so long as it can insulate between the semiconductor chip 41 and the sealing conductor 61. The field insulation film 131 can have a thickness of 0.1 μm or more but 5 μm or less.

The separation structure 130 is formed on the first principal surface 42 of the semiconductor chip 41, and extends in the shape of a stripe along the sealing conductor 61 as seen in a plan view. In the embodiment, the separation structure 130 is formed in a quadrangular ring shape (specifically, a rectangular ring shape) as seen in a plan view. The separation structure 130 has a connection portion 132 to which the bottom end part of the sealing conductor 61 (i.e., the sealing via conductors 65) is connected. The connection portion 132 can form an anchor portion into which the bottom end part of the sealing conductor 61 (i.e., the sealing via conductors 65) is anchored toward the semiconductor chip 41. Needless to say, the connection portion 132 can be formed to be flush with the principal surface of the separation structure 130.

The separation structure 130 includes an inner end part 130A at the device region 62 side, an outer end part 130B at the outer region 63 side, and a main body part 130C between the inner and outer end parts 130A and 130B. As seen in a plan view, the inner end part 130A defines the region where the second functional device 60 is formed (i.e., the device region 62). The inner end part 130A can be formed integrally with an insulation film (not illustrated) formed on the first principal surface 42 of the semiconductor chip 41.

The outer end part 130B is exposed on the chip side walls 44A to 44D of the semiconductor chip 41, and is continuous with the chip side walls 44A to 44D of the semiconductor chip 41. More specifically, the outer end part 130B is formed so as to be flush with the chip side walls 44A to 44D of the semiconductor chip 41. The outer end part 130B constitutes a polished surface between, to be flush with, the chip side walls 44A to 44D of the semiconductor chip 41 and the insulation side walls 53A to 53D of the insulation layer 51. Needless to say, an embodiment is also possible where the outer end part 130B is formed within the first principal surface 42 at intervals from the chip side walls 44A to 44D.

The main body part 130C has a flat surface that extends substantially parallel to the first principal surface 42 of the semiconductor chip 41. The main body part 130C has the connection portion 132 to which the bottom end part of the sealing conductor 61 (i.e., the sealing via conductors 65) is connected. The connection portion 132 is formed in the main body part 130C, at intervals from the inner and outer end parts 130A and 130B. The separation structure 130 can be implemented in many ways other than in the form of a field insulation film 131.

Referring to FIGS. 15 and 16, the semiconductor device 5 further includes an inorganic insulation layer 140 formed on the insulation principal surface 52 of the insulation layer 51 so as to cover the sealing conductor 61. The inorganic insulation layer 140 can be called a passivation layer. The inorganic insulation layer 140 protects the insulation layer 51 and the semiconductor chip 41 from above the insulation principal surface 52.

In the embodiment, the inorganic insulation layer 140 has a stacked structure composed of a first inorganic insulation layer 141 and a second inorganic insulation layer 142. The first inorganic insulation layer 141 can contain silicon oxide. Preferably, the first inorganic insulation layer 141 contains USG (undoped silicate glass), which is undoped silicon oxide. The first inorganic insulation layer 141 can have a thickness of 50 nm or more but 5000 nm or less. The second inorganic insulation layer 142 can contain silicon nitride. The second inorganic insulation layer 142 can have a thickness of 500 nm or more but 5000 nm or less. Increasing the total thickness of the inorganic insulation layer 140 helps increase the dielectric strength voltage above the high-potential coils 23.

In a configuration where the first inorganic insulation layer 141 is made of USG and the second inorganic insulation layer 142 is made of silicon nitride, USG has the higher dielectric breakdown voltage (V/cm) than silicon nitride. In view of this, when thickening the inorganic insulation layer 140, it is preferable to form the first inorganic insulation layer 141 thicker than the second inorganic insulation layer 142.

The first inorganic insulation layer 141 can contain at least one of BPSG (boron-doped phosphor silicate glass) and PSG (phosphorus silicate glass) as examples of silicon oxide. In that case, however, since the silicon oxide contains a dopant (boron or phosphorus), for an increased dielectric strength voltage above the high-potential coils 23, it is particularly preferable to form the first inorganic insulation layer 141 of USG. Needless to say, the inorganic insulation layer 140 can have a single-layer structure composed of either the first or second inorganic insulation layer 141 or 142.

The inorganic insulation layer 140 covers the entire area of the sealing conductor 61, and has a plurality of low-potential pad openings 143 and a plurality of high-potential pad openings 144 that are formed in a region outside the sealing conductor 61. The plurality of low-potential pad openings 143 expose the plurality of low-potential terminals 11 respectively. The plurality of high-potential pad openings 144 expose the plurality of high-potential terminals 12 respectively. The inorganic insulation layer 140 can have overlap parts that overlap circumferential edge parts of the low-potential terminals 11. The inorganic insulation layer 140 can have overlap parts that overlap circumferential edge parts of the high-potential terminals 12.

The semiconductor device 5 further includes an organic insulation layer 145 that is formed on the inorganic insulation layer 140. The organic insulation layer 145 can contain photosensitive resin. The organic insulation layer 145 can contain at least one of polyimide, polyamide, and polybenzoxazole. In the embodiment, the organic insulation layer 145 contains polyimide. The organic insulation layer 145 can have a thickness of 1 μm or more but 50 μm or less.

Preferably, the organic insulation layer 145 has a thickness larger than the total thickness of the inorganic insulation layer 140. Moreover, preferably, the inorganic and organic insulation layers 140 and 145 together have a total thickness larger than the distance D2 between the low- and high-potential coils 22 and 23. In that case, preferably, the inorganic insulation layer 140 has a total thickness of 2 μm or more but 10 μm or less. Preferably, the organic insulation layer 145 has a thickness of 5 μm or more but 50 μm or less. Such structures help suppress an increase in the thicknesses of the inorganic and organic insulation layers 140 and 145 while appropriately increasing the dielectric strength voltage above the high-potential coil 23 owing to the stacked film of the inorganic and organic insulation layers 140 and 145.

The organic insulation layer 145 includes a first part 146 that covers a low-potential side region and a second part 147 that covers a high-potential side region. The first part 146 covers the sealing conductor 61 across the inorganic insulation layer 140. The first part 146 has a plurality of low-potential terminal openings 148 through which the plurality of low-potential terminals 11 (low-potential pad openings 143) are respectively exposed in a region outside the sealing conductor 61. The first part 146 can have overlapping parts that overlap circumferential edges (overlap parts) of the low-potential pad openings 143.

The second part 147 is formed at an interval from the first part 146, and exposes the inorganic insulation layer 140 between the first and second parts 146 and 147. The second part 147 has a plurality of high-potential terminal openings 149 through which the plurality of high-potential terminals 12 (high-potential pad openings 144) are respectively exposed. The second part 147 can have overlap parts that overlap circumferential edges (overlap parts) of the high-potential pad openings 144.

The second part 147 covers the transformers 21A to 21D and the dummy pattern 85 together. Specifically, the second part 147 covers the plurality of high-potential coils 23, the plurality of high-potential terminals 12, a first high-potential dummy pattern 87, a second high-potential dummy pattern 88, and a floating dummy pattern 121 together.

In a structure that lacks the organic insulation layer 145, a filler contained in the package housing (molding resin) may cause damage to the plurality of high-potential coils 23, the plurality of high-potential terminals 12, the sealing conductor 61, the first high-potential dummy pattern 87, the second high-potential dummy pattern 88, and the floating dummy pattern 121. Damage of this kind is called filler corrosion.

The organic insulation layer 145 protect, from the filler contained in the package housing (molding resin), the plurality of high-potential coils 23, the plurality of high-potential terminals 12, the sealing conductor 61, the first high-potential dummy pattern 87, the second high-potential dummy pattern 88, and the floating dummy pattern 121. The slit between the first and second parts 146 and 147 functions as an anchor in the package housing (molding resin).

A part of the package housing (molding resin) fits in the slit between the first and second parts 146 and 147, and is connected to the inorganic insulation layer 140. This helps increase the adhesion of the package housing (molding resin) to the semiconductor device 5. Needless to say, the first and second parts 146 and 147 can be formed integrally. The organic insulation layer 145 may include only either of the first and second parts 146 and 147. In that case, however, filler corrosion needs to be coped with.

The present invention can be implemented in any other embodiments. The embodiment described above deals with an example where a first functional device 45 and a second functional device 60 are formed. An embodiment is however also possible that only has a second functional device 60, with no first functional device 45. In that case, the dummy pattern 85 may be omitted. This structure provides, with respect to the second functional device 60, effects similar to those mentioned in connection with the first embodiment (except those associated with the dummy pattern 85).

That is, in a case where a voltage is applied to the second functional device 60 via the low- and high-potential terminals 11 and 12, it is possible suppress unnecessary conduction between the high-potential terminal 12 and the sealing conductor 61. Likewise, in a case where a voltage is applied to the second functional device 60 via the low- and high-potential terminals 11 and 12, it is possible suppress unnecessary conduction between the low-potential terminal 11 and the sealing conductor 61.

The embodiment described above deals with an example where a second functional device 60 is formed. The second functional device 60 however is not essential, and can be omitted.

The embodiment described above deals with an example where a dummy pattern 85 is formed. The dummy pattern 85 however is not essential, and can be omitted.

The embodiment described above deals with an example where the first functional device 45 is of a multichannel type that includes a plurality of transformers 21. It is however also possible to employ a single-channel first functional device 45 that includes a single transformer 21.

<Transformer Layout>

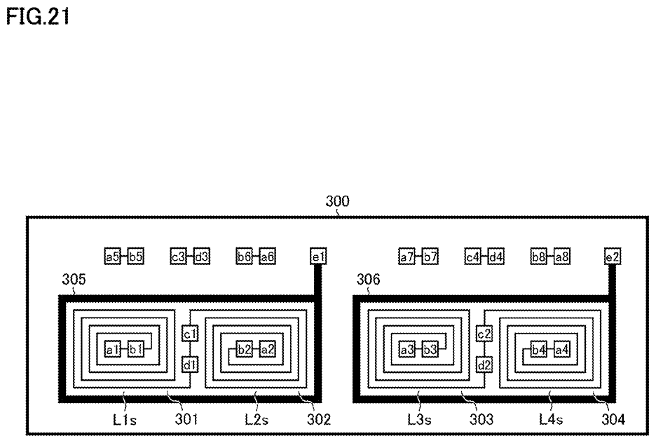

FIG. 21 is a plan view (top view) schematically showing one example of transformer layout in a two-channel transformer chip 300 (corresponding to the semiconductor device 5 described previously). The transformer chip 300 shown there includes a first transformer 301, a second transformer 302, a third transformer 303, a fourth transformer 304, a first guard ring 305, a second guard ring 306, pads a1 to a8, pads b1 to b8, pads c1 to c4, and pads d1 to d4.

In the transformer chip 300, the pads a1 and b1 are connected to one terminal of the secondary coil L1s of the first transformer 301, and the pads c1 and d1 are connected to the other terminal of that secondary coil L1s. The pads a2 and b2 are connected to one terminal of the secondary coil L2s of the second transformer 302, and the pads c1 and d1 are connected to the other terminal of that secondary coil L2s.

Moreover, the pads a3 and b3 are connected to one terminal of the secondary coil L3s of the third transformer 303, and the pads c2 and d2 are connected to the other terminal of that secondary coil L3s. The pads a4 and b4 are connected to one terminal of the secondary coil L4s of the fourth transformer 304, and the pads c2 and d2 are connected to the other terminal of that secondary coil L4s.

FIG. 21 does not show any of the primary coils L1p, L2p, L3p, and L4p of the first, second, third, and fourth transformers 301, 302, 303, and 304, respectively. The primary coils L1p to L4p basically have structures similar to those of the secondary coils L1s to L4s respectively, and are disposed right below the secondary coils L1s to L4s, respectively, so as to face them.

Specifically, the pads a5 and b5 are connected to one terminal of the primary coil L1p of the first transformer 301, and the pads c3 and d3 are connected to the other terminal of that primary coil L1p. Likewise, the pads a6 and b6 are connected to one terminal of the primary coil L2p of the second transformer 302, and the pads c3 and d3 are connected to the other terminal of that primary coil L2p.

Likewise, the pads a7 and b7 are connected to one terminal of the primary coil L3p of the third transformer 303, and the pads c4 and d4 are connected to the other terminal of that primary coil L3p. Likewise, the pads a8 and b8 are connected to one terminal of the primary coil L4p of the fourth transformer 304, and the pads c4 and d4 are connected to the other terminal of that primary coil L4p.

The pads a5 to a8, the pads b5 to b8, the pads c3 and c4, and the pads d3 and d4 mentioned above are each led from inside the transformer chip 300 to its surface across an unillustrated via.

Of the plurality of pads mentioned above, the pads a1 to a8 each correspond to a first current feed pad, and the pads b1 to b8 each correspond to a first voltage measurement pad; the pads c1 to c4 each correspond to a second current feed pad, and the pads d1 to d4 each correspond to a second voltage measurement pad.

Thus, the transformer chip 300 of this configuration example permits, during its defect inspection, accurate measurement of the series resistance component across each coil. It is thus possible not only to reject defective products with a broken wire in a coil but also to appropriately reject defective products with an abnormal resistance value in a coil (e.g., a midway short circuit between coils), and hence to prevent defective products from being distributed in the market.

For a transformer chip 300 that has passed the defect inspection mentioned above, the plurality of pads described above can be used for connection with a primary-side chip and a secondary-side chip (e.g., the controller chip 210 and the driver chip 220 described previously).

Specifically, the pads a1 and b1, the pads a2 and b2, the pads a3 and b3, and the pads a4 and b4 can each be connected to one of the signal input and output terminals of the secondary-side chip; the pads c1 and d1 and the pads c2 and d2 can each be connected to a common voltage application terminal (GND2) of the secondary-side chip.

On the other hand, the pads a5 and b5, the pads a6 and b6, the pads a7 and b7, and the pads a8 and b8 can each be connected to one of the signal input and output terminals of the primary-side chip; the pads c3 and d3 and the pads c4 and d4 can each be connected to a common voltage application terminal (GND1) of the primary-side chip.

Here, as shown in FIG. 13, the first to fourth transformers 301 to 304 are so arranged as to be coupled for each signal transmission direction. In terms of what is shown in the diagram, for example, the first and second transformers 301 and 302, which transmit a signal from the primary-side chip to the secondary-side chip, are coupled into a first pair by the first guard ring 305. Likewise, for example, the third and fourth transformers 303 and 302, which transmit a signal from the secondary-side chip to the primary-side chip, are coupled into a second pair by the second guard ring 306.

Such coupling is intended, in a structure where the primary and secondary coils of each of the first to fourth transformers 301 to 304 are formed so as to be stacked on each other in the up-down direction of the substrate, to obtain a desired withstand voltage between the primary and secondary coils. The first and second guard rings 305 and 306 are however not essential elements.

The first and second guard rings 305 and 306 can be connected via pads e1 and e2, respectively, to a low-impedance wiring such as a grounded terminal.

In the transformer chip 300, the pads c1 and d1 are shared between the secondary coils L1s and L2s. The pads c2 and d2 are shared between the secondary coils L3s and L4s. The pads c3 and d3 are shared between the primary coils L1p and L2p. The pads c4 and d4 are shared between the primary coils L3p and L4p. This configuration helps reduce the number of pads and helps make the transformer chip 300 compact.

Moreover, as shown in FIG. 21, the primary and secondary coils of the first to fourth transformers 301 to 304 are preferably each wound in a rectangular shape (or, with the corners rounded, in a running-track shape) as seen in a plan view of the transformer chip 300. This configuration helps increase the area over which the primary and secondary coils overlap each other and helps enhance the transmission efficiency across the transformers.

Needless to say, the illustrated transformer layout is merely an example; any number of coils of any shape can be disposed in any layout, and pads can be disposed in any layout. Any of the chip structure, transformer layouts, etc. described above can be applied to semiconductor devices in general that have a coil integrated in a semiconductor chip.

<Introduction of Shield Electrodes>

Presented next will be a novel structure of the transformer chip 230 with which it is possible to effectively suppress common-mode noise itself without relying on a noise canceller 225 (FIG. 8).

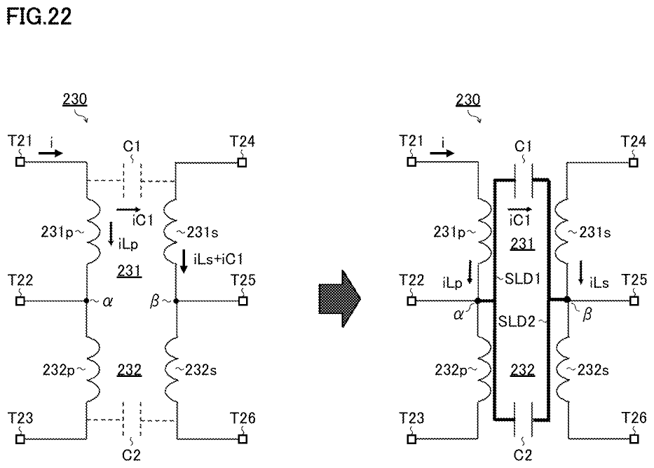

FIG. 22 is a diagram showing an example of shield electrodes introduced in the transformer chip 230. In the left half of the diagram is shown, for comparison, a transformer chip 230 of a known structure with no shield electrodes introduced in it. By contrast, in the right half of the diagram is shown a transformer chip 230 of the novel structure with shield electrodes SLD1 and SLD2 introduced in it. Only either of the shield electrodes SLD1 and SLD2 may be introduced.

In the following description, the primary coils 231p and 232p and the secondary coils 231s and 232s will occasionally be referred to as the primary windings 231p and 232p and secondary windings 231s and 232s respectively.

As shown also in FIG. 10 referred to earlier, the transformer chip 230 has six external terminals T21 to T26. The external terminal T21 is connected to the first terminal of the primary winding 231p; the external terminal T22 is connected to the second terminal of the primary winding 231p and to the second terminal of the primary winding 232p; and the external terminal T23 is connected to the second terminal of the primary winding 232p. On the other hand, the external terminal T24 is connected to the first terminal of the secondary winding 231s; the external terminal T25 is connected to the second terminal of the secondary winding 231s and to the second terminal of the secondary winding 232s; and the external terminal T26 is connected to the second terminal of the secondary winding 232s.

For structural reasons, the transformers 231 and 232 are accompanied by coil-to-coil capacitances C1 and C2 between the primary and secondary windings 231p and 231s and between the primary and secondary windings 232p and 232s respectively.

The transformer chip 230 of the novel structure (at right in the diagram) is additionally provided with shield electrodes SLD1 and SLD2 formed so as to be interposed between, on one side, the primary windings 231p and 232p and, on the other side, the secondary windings 231s and 232s.

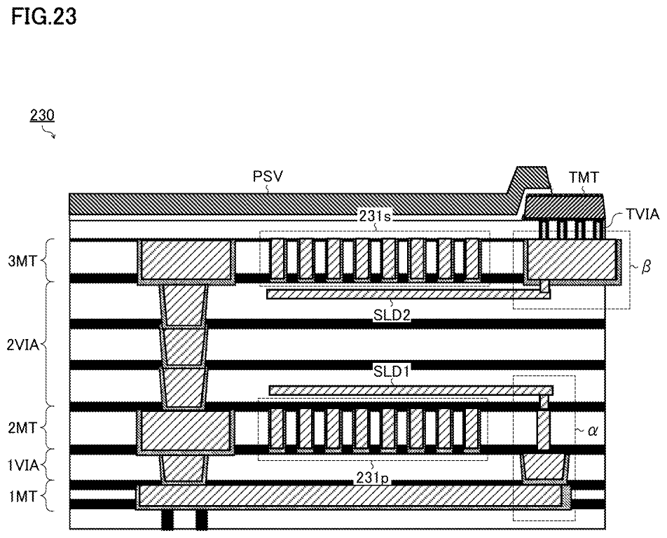

FIG. 23 is a diagram showing the vertical structure of the transformer chip 230 provided with the shield electrodes SLD1 and SLD2. As shown there, the transformer chip 230 of the novel structure has a stack of metal layers (wiring layers) 1MT, 2MT, and 3MT formed in this order from the bottom. The metal layers 1MT and 2MT are electrically connected together by a single-layer via 1VIA. The metal layers 2MT and 3MT are electrically connected together by a three-layer via 2VIA. The topmost surface of the transformer chip 230 is covered by a passivation layer PSV except where pads are exposed.

The primary winding 231p is formed in the metal layer 2MT, which is the middle layer. On the other hand, the secondary winding 231s is formed in the metal layer 3MT, which is the topmost layer, so as to be magnetically coupled with the primary winding 231p. A similar description applies to, though not illustrated, the primary and secondary windings 232p and 232s.

Here, the shield electrodes SLD1 and SLD2 are both formed in a region lying between the metal layers 2MT and 3MT so as to be interposed between the primary and secondary windings 231p and 231s (or the primary and secondary windings 232p and 232s).

As shown in FIGS. 22 and 23, the shield electrode SLD1 is connected to the ground terminal a of each of the primary windings 231p and 232p (i.e., the external terminal T22 fed with the ground potential GND1 of the primary circuit system 200p). On the other hand, the shield electrode SLD2 is connected to the ground terminal 13 of each of the secondary windings 231s and 232s (i.e. the external terminal T25 fed with the ground potential GND2 of the secondary circuit system 200s).

For example, in terms of what is shown in FIG. 23, the shield electrodes SLD1 and SLD2 are formed immediately above the primary winding 231p and immediately below the secondary winding 231s, respectively, so as to extend in the left-right direction in the diagram, and are connected at their right ends to the ground terminals a and 13 respectively. The ground terminal 13 conducts via a via TVIA to a pad TMT (corresponding to the external terminal T25). On the other hand, the ground terminal a is connected via the metal layers 1MT to 3MT and the vias 1VIA and 2VIA to the external terminal T22 (not illustrated).

Referring back to FIG. 22, a comparison of the known and novel structures continues. With the transformer chip 230 of the known structure (at left in the diagram), when common-mode noise is superposed, signals with shifted phases are transmitted via the coil-to-coil capacitances C1 and C2. This necessitates measures against noise in the driver chip 220 (like introduction of a noise canceller 225).

Even if a noise canceller 225 (FIG. 8) is introduced, if a noise pulse occurs at such a timing that it overlaps a regular pulse, the former may unexpectedly mask the latter to produce a delay corresponding to one pulse (see time point t26 in FIG. 9). Another drawback is that the noise canceller 225, including the delay circuits DLY1 to DLY4, limits the band width.

By contrast, with the transformer chip 230 of the novel structure (at right in the diagram), the current that passes via the coil-to-coil capacitances C1 and C2 when common-mode noise is superposed is diverted via the shield electrodes SLD1 and SLD2 to the ground terminals a and (3. That is, the common-mode noise transmitted via the coil-to-coil capacitances C1 and C2 can itself be effectively reduced. It is thus possible to suppress malfunctioning without relying on a noise canceller 225.

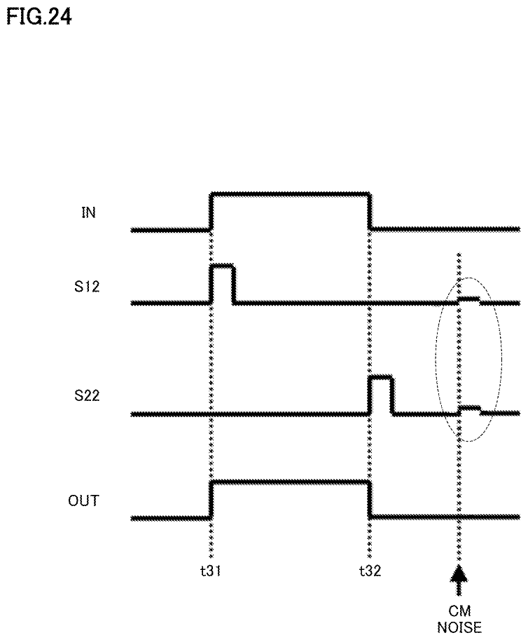

FIG. 24 is a diagram showing the effect of noise reduction achieved by the introduction of the shield electrodes SLD1 and SLD2, and depicts, like FIG. 3 referred to earlier, from top down, the input pulse signal IN, the reception pulse signals S12 and S22, and the output pulse signal OUT.

First, regular pulse signal transmission operation will be described in brief. When at time point t31 the input pulse signal IN rises to high level, the transformer 231 is pulse-driven, and thus a regular pulse rises in the reception pulse signal S12. As a result, the output pulse signal OUT rises to high level. When at time point t32 the input pulse signal IN falls to low level, the transformer 232 is pulse-driven, and thus a regular pulse rises in the reception pulse signal S22. As a result, the output pulse signal OUT falls to low level. This is so far no different from what has been described previously.

On the other hand, a false signal ascribable to common-mode noise appears in the transformers 231 and 232 simultaneously. Here, however, the shield electrodes SLD1 and SLD2 act to greatly reduce the common-mode noise itself that is superposed on the reception pulse signals S12 and S22. As a result, the threshold voltage Vth of the buffers 221 and 222 is unlikely to be exceeded, and it is thus possible to prevent malfunctioning of the output pulse signal OUT.

<Layout and Signal Transmission Performance of Shield Electrodes>

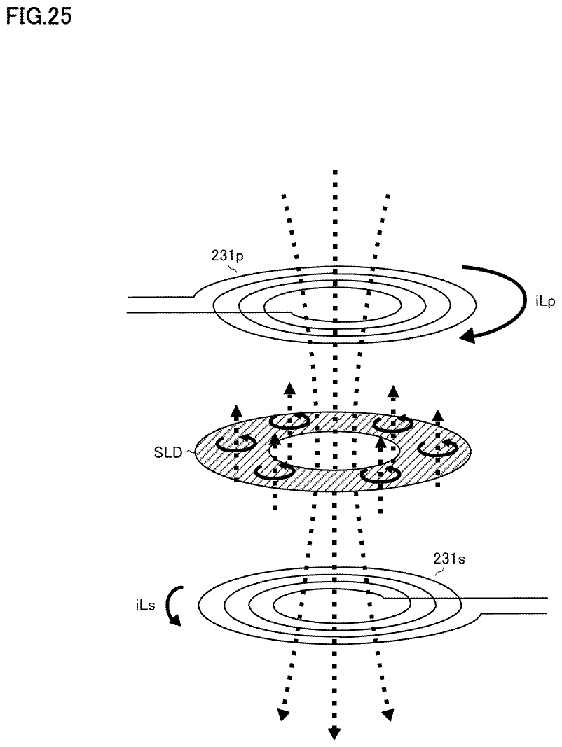

FIGS. 25 to 27 are diagrams showing the relationship of the layout of a shield electrode SLD (corresponding to the shield electrodes SLD1 and SLD2 described above) with its signal transmission performance. In the diagrams, solid-line arrows represent current, and broken-line arrows represent electric field.

In FIG. 25, the shield electrode SLD is formed in a plain solid pattern so as to be interposed between the primary and secondary windings 231p and 231s (or the primary and secondary windings 232p and 232s). This layout is expected to produce countless eddy currents in the shield electrode SLD and thus suffer from significant transmission inhibition due to a diamagnetic field.

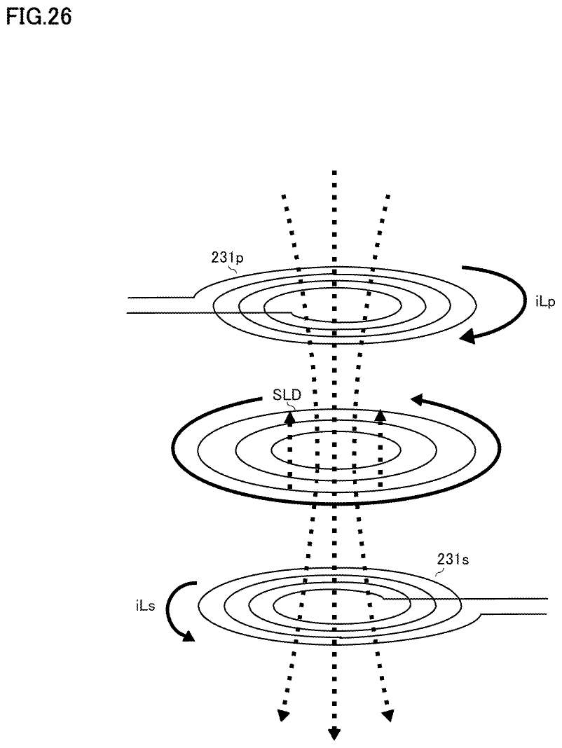

In FIG. 26, the shield electrode SLD is formed to be composed of a plurality of segments in the shape of concentric circles or concentric rings as seen in a plan view (in a comb-tooth shape as seen in a sectional view) so as to be interposed between the primary and secondary windings 231p and 231s (or the primary and secondary windings 232p and 232s). This layout, as compared with the plain solid pattern mentioned above (FIG. 25), is expected to suppress eddy currents and thus suffer from less transmission inhibition due to a diamagnetic field. Even so, eddy currents occur within the loops of the shield electrode SLD, and this makes it difficult to completely eliminate transmission inhibition due to a diamagnetic field.

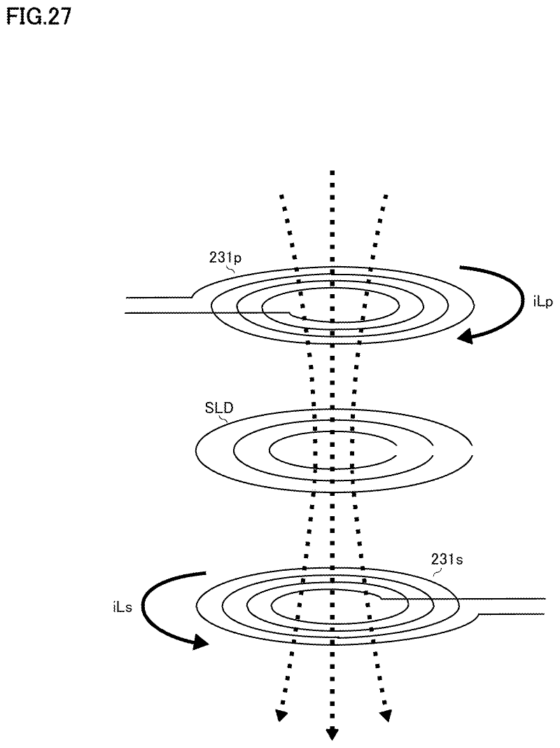

In FIG. 27, the shield electrode SLD is formed, as in FIG. 26 referred to above, to be composed of a plurality of segments in the shape of concentric circles or concentric rings as seen in a plan view (in a comb-tooth shape as seen in a sectional view) so as to be interposed between the primary and secondary windings 231p and 231s (or the primary and secondary windings 232p and 232s) and in addition, here, in the shape of open rings as seen in a plan view. That is, the shield electrode SLD has no loops that act as passages for eddy currents, and this makes it possible to minimize transmission inhibition due to a diamagnetic field.

As described above, an ingenious layout of the shield electrode SLD helps suppress a drop in signal transmission performance.

<Planar Layout of Shield Electrodes>

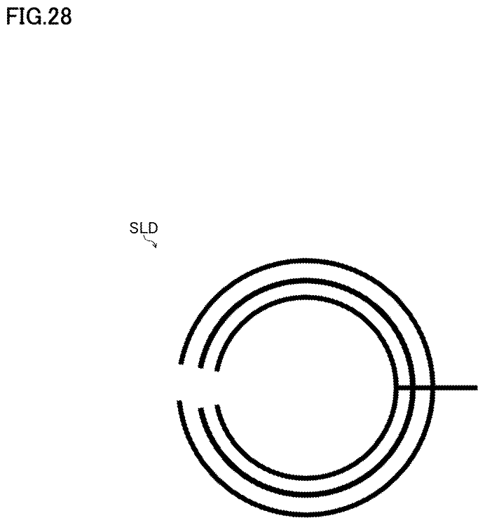

FIG. 28 is a diagram showing a first exemplary planar layout of a shield electrode SLD. The shield electrode SLD shown there is formed to be composed of a plurality of segments in the shape of concentric circuits or concentric rings as seen in a plan view and in addition in the shape of open rings as seen in a plan view. This planar layout corresponds to the one described above and shown in FIG. 27 (C-shaped pattern).

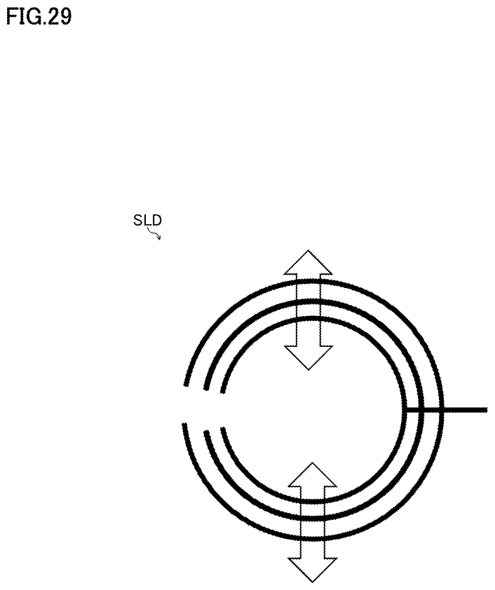

FIG. 29 is a diagram showing a second exemplary planar layout of a shield electrode SLD. The shield electrode SLD shown there is similar to the one described above and shown in FIG. 27 (C-shaped pattern) but additionally allows, as indicated by hollow arrows, its size (radius), line/space ratio (L/S ratio, i.e., line width to line interval ratio), etc. to be changed as desired.

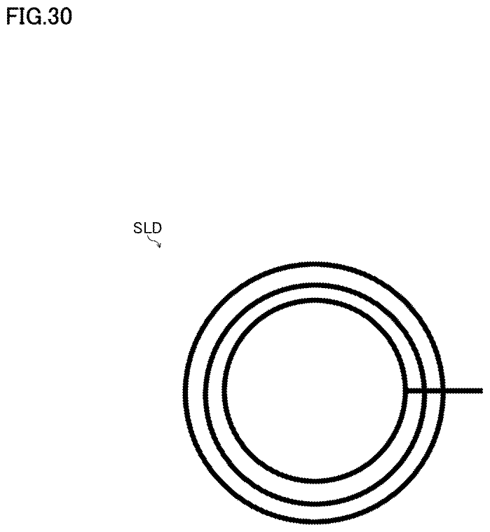

FIG. 30 is a diagram showing a third exemplary planar layout of a shield electrode SLD. The shield electrode SLD shown there is formed to be composed of a plurality of segments in the shape of concentric circuits or concentric rings as seen in a plan view. This planar layout corresponds to the one described above and shown in FIG. 26 (O-shaped pattern). As a layout similar to the O-shaped pattern, a shield electrode SLD may be formed in a shape quite similar to those of the primary and secondary windings.

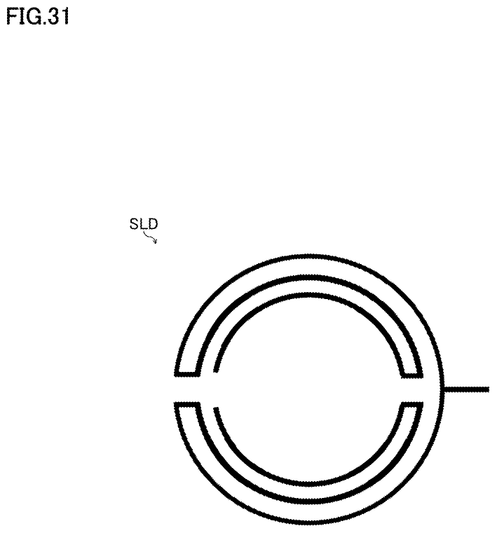

FIG. 31 is a diagram showing a fourth exemplary planar layout of a shield electrode SLD. The shield electrode SLD shown there has a planar layout similar to the one described above and shown in FIG. 28 (C-shaped pattern) and is here formed in the pattern of a single continuous stroke. Patterns like this too help suppress eddy currents (hence transmission inhibition due to a diamagnetic field).

<Sectional Structure of Shield Electrodes>

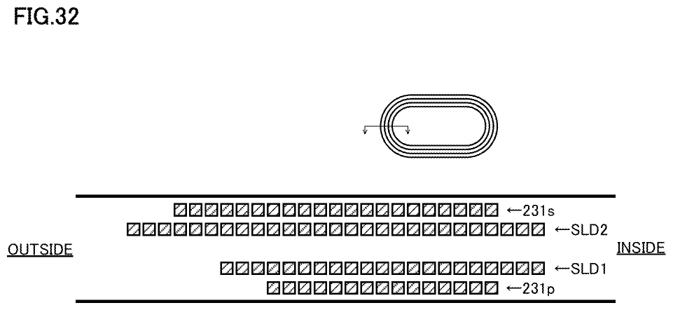

FIG. 32 is a diagram showing a first exemplary sectional structure of the primary and secondary windings 231p and 231s (or the primary and secondary windings 232p and 232s) and the shield electrodes SLD1 and SLD2. The shield electrodes SLD1 and SLD2 shown there are formed up to outward of (beyond) the outermost circumferences of the primary and secondary windings 231p and 231s respectively and up to inward of (beyond) the innermost circumferences of the primary and secondary windings 231p and 231s respectively. Moreover, the shield electrodes SLD1 and SLD2 are designed to have a line/space ratio equal to that of the primary and secondary windings 231p and 231s respectively.

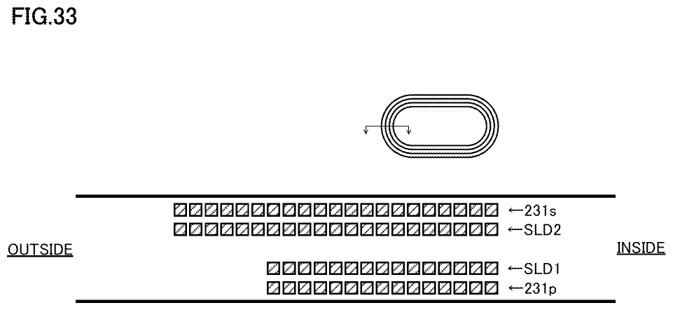

FIG. 33 is a diagram showing a second exemplary sectional structure of the primary and secondary windings 231p and 231s (or the primary and secondary windings 232p and 232s) and the shield electrodes SLD1 and SLD2. The shield electrodes SLD1 and SLD2 shown there are formed up to the same position as the outermost circumferences of the primary and secondary windings 231p and 231s respectively and up to the same position as the innermost circumferences of the primary and secondary windings 231p and 231s respectively.

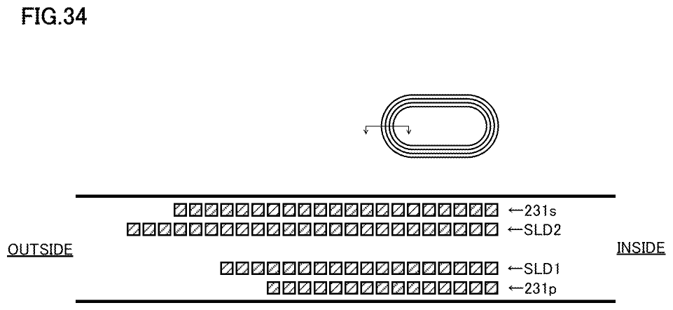

FIG. 34 is a diagram showing a third exemplary sectional structure of the primary and secondary windings 231p and 231s (or the primary and secondary windings 232p and 232s) and the shield electrodes SLD1 and SLD2. The shield electrodes SLD1 and SLD2 shown there are formed up to outward of (beyond) the outermost circumferences of the primary and secondary windings 231p and 231s respectively and up to the same position as the innermost circumferences of the primary and secondary windings 231p and 231s respectively.

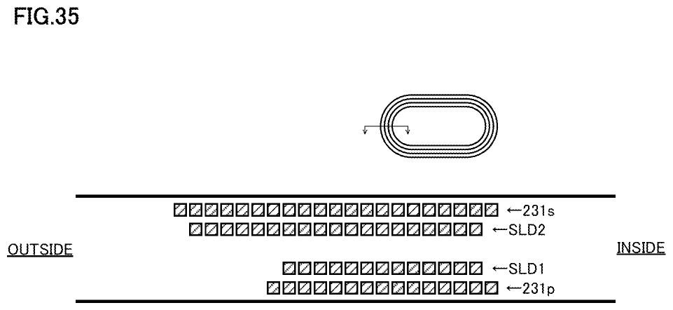

FIG. 35 is a diagram showing a fourth exemplary sectional structure of the primary and secondary windings 231p and 231s (or the primary and secondary windings 232p and 232s) and the shield electrodes SLD1 and SLD2. The shield electrodes SLD1 and SLD2 shown there are formed up to inward of (short of) the outermost circumferences of the primary and secondary windings 231p and 231s respectively and up to outward of (short of) the innermost circumferences of the primary and secondary windings 231p and 231s respectively.

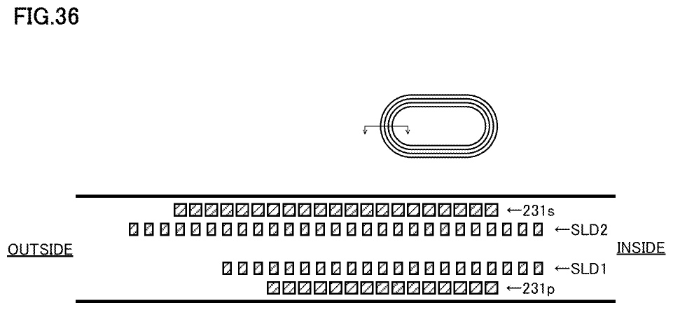

FIG. 36 is a diagram showing a fifth exemplary sectional structure of the primary and secondary windings 231p and 231s (or the primary and secondary windings 232p and 232s) and the shield electrodes SLD1 and SLD2. The shield electrodes SLD1 and SLD2 shown there are formed, as in the first exemplary sectional structure (FIG. 33), up to outward of (beyond) the outermost circumferences of the primary and secondary windings 231p and 231s respectively and up to inward of (beyond) the innermost circumferences of the primary and secondary windings 231p and 231s respectively. Moreover, here, the shield electrodes SLD1 and SLD2 are designed to have a line/space ratio lower than that of the primary and secondary windings 231p and 231s respectively.

As described above, for each of the primary and secondary windings 231p and 231s and the shield electrodes SLD1 and SLD2, its size and line/space ratio can be adjusted as desired. For example, though not illustrated in the diagrams referred to above, desired structures can be adopted such as one in which the upper structure (the secondary winding 231s and the shield electrode SLD2) is formed larger than the lower structure (the primary winding 231p and the shield electrode SLD1) and one in which the parts constituting the lower and upper structures are given gradually increasing sizes from bottom up.

<Effect of the Introduction of Shield Electrodes>

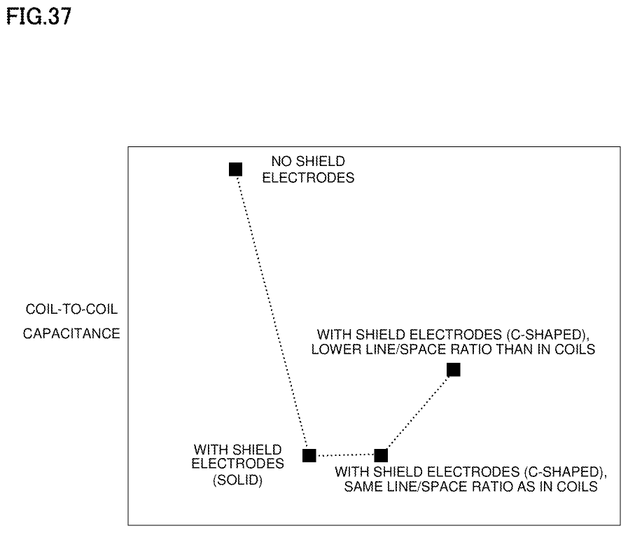

FIG. 37 is a diagram showing the relationship of the presence or absence of shield electrodes with the coil-to-coil capacitance. As shown there, introducing shield electrodes helps reduce the coil-to-coil capacitance in the transformer chip.

Moreover, as will be understood from the diagram, as to the planar layout of the shield electrode, using a plain solid pattern (FIG. 25) or a C-shaped pattern (FIG. 27) does not make a notable difference in the effect of reducing the coil-to-coil capacitance. In view of this, it can be said that a preferable planar layout of the shield electrode is a C-shaped pattern, which suffers from less transmission inhibition due to a diamagnetic field than a plain solid pattern.

On the other hand, as to the line/space ratio of the shield electrode, the lower it is, the less signal transmission is expected to be inhibited but also the lower the effect of reducing the coil-to-coil capacitance. A trade-off between those two factors has to be given consideration in designing. In terms of what is shown in FIG. 37, it is preferable that a shield electrode be designed to have a line/space ratio (diameter) equal to that of the primary and secondary windings.

<Planar Layout of Coils and Shield Electrodes>

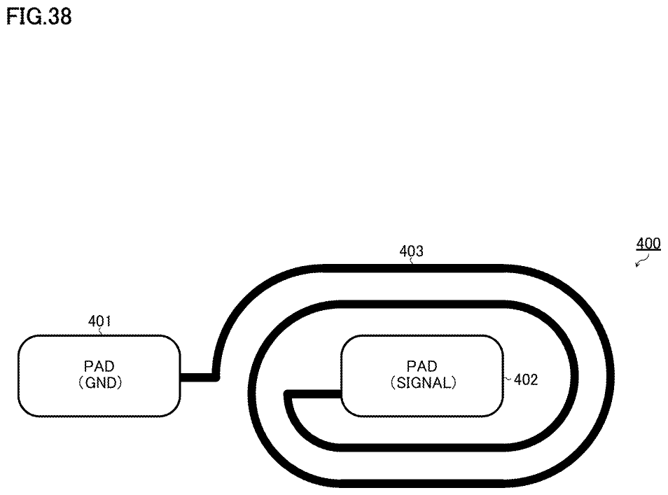

FIG. 38 is a diagram showing a planar layout of pads and a coil formed in the transformer chip. The diagram depicts the pads 401 and 402 and the coil 403 formed in a transformer chip 400 (corresponding to the transformer chip 230 and the like described previously).

In comparison with what is shown in FIG. 10 referred to earlier, the pad 401 corresponds to, for example, the external terminal T25 (the GND pad of the secondary circuit system 200s) and the pad 402 corresponds to, for example, the external terminal T24 or T26 (the signal pad of the secondary circuit system 200s). The coil 403 corresponds to, for example, the secondary winding 231s or 232s.

The coil 403 is laid in a spiral shape so as to surround the pad 402. Specifically, in terms of what is shown in the diagram, as seen in a plan view of the transformer chip 400, the coil 403 is laid so as to describe a corner-rounded rectangular shape (a planar shape like a running track) around the pad 402 by tracing a locus that, while moving around, moves away from the center (when traced backward, moves closer to the center). Similar layouts are shown also in FIGS. 10, 13, etc. referred to earlier.

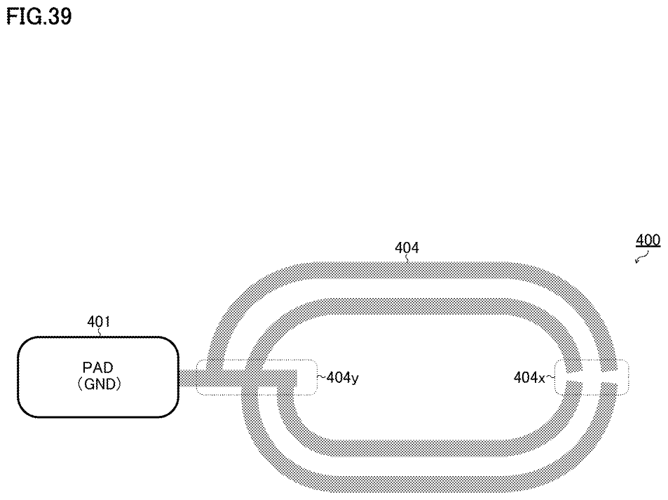

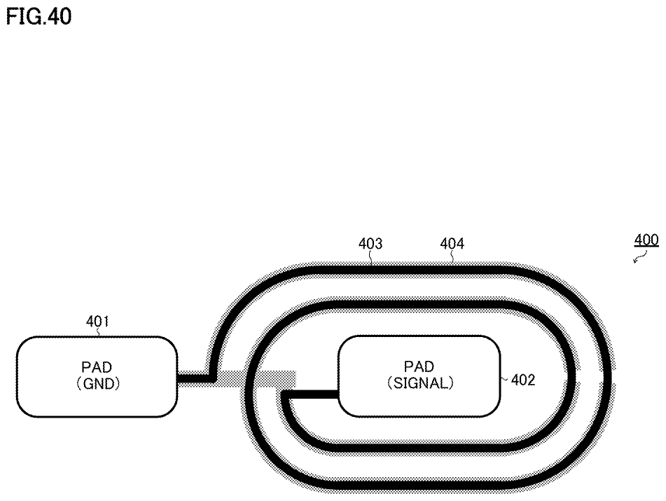

FIG. 39 is a diagram showing a first planar layout of a shield electrode 404 that overlaps the coil 403 in FIG. 38. FIG. 40 is a diagram having FIGS. 38 and 39 overlaid on each other.

The shield electrode 404 corresponds to, for example, the shield electrode SLD1 or SLD2 in FIG. 23, or the shield electrode SLD in FIG. 27 or 28. The shield electrode 404 is formed in a wiring layer different from that of the coil 403 (e.g., the wiring layer just under the wiring layer in which the coil 403 is formed).

The shield electrode 404 is laid so as to trace the coil 403 such that it, as seen in a plan view of the transformer chip 400, partly or wholly (in the diagram, over a large part, 80% or more, of it) overlaps the coil 403. A layout pattern like this helps enhance the effect of reducing common-mode noise.

In terms of what is shown in FIG. 39, specifically, the shield electrode 404 is laid basically in the same shape (spiral shape) as the coil 403 but has open ends 404x to inhibit eddy currents. That is, the spiral shape of the shield electrode 404 is broken at where it has the open ends 404x. Accordingly, the shield electrode 404 has no loops that act as passages for eddy currents, and this makes it possible to minimize transmission inhibition due to a diamagnetic field. This is the same as what has been described with reference to FIG. 27 referred to previously.

Every part of the shield electrode 404 conducts via a coupling portion 404y to the pad 401. This leaves unaffected the effect of reducing common-mode noise. This, though obvious from FIG. 28 referred to previously, deserves an express mention here.

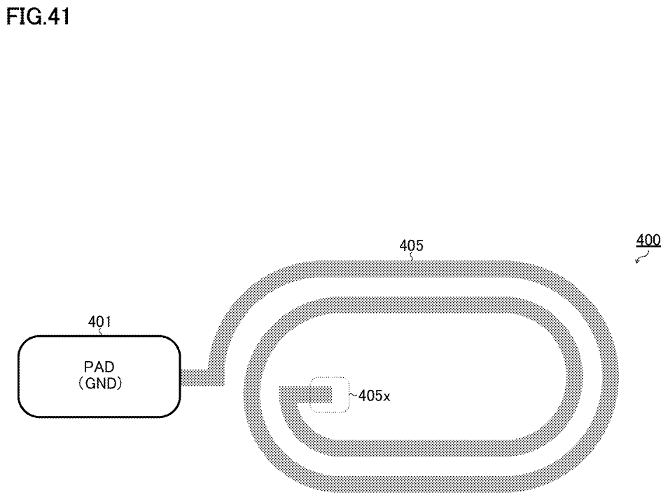

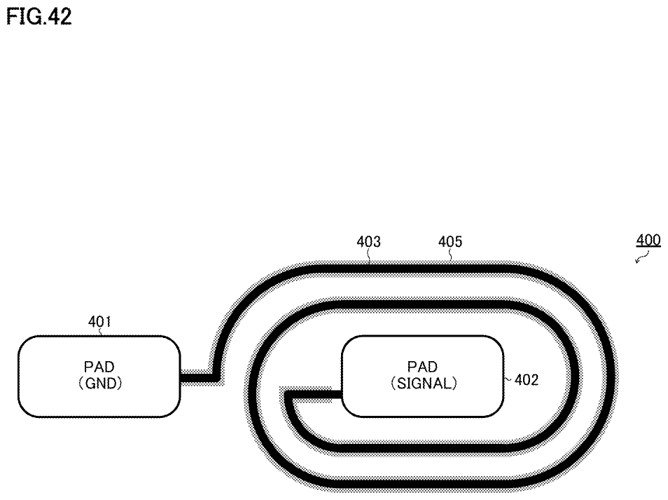

FIG. 41 is a diagram showing a second planar layout of a shield electrode 405 that overlaps the coil 403 in FIG. 38. FIG. 42 is a diagram having FIGS. 38 and 41 overlaid on each other.

Like the shield electrode 404 described above, the shield electrode 405 is laid so as to trace the coil 403 such that it, as seen in a plan view of the transformer chip 400, partly or wholly (in the diagram, over nearly 100% of it) overlaps the coil 403.

Unlike the shield electrode 404 described above, however, the shield electrode 405 has an open end 405x at its terminal end instead of in the middle of its spiral shape. A layout pattern like this helps increase the area over which the coil 403 overlaps the shield electrode 405, and thus helps further enhance the effect of reducing common-mode noise.

<Planar Layout of Shield Electrodes (Summary)>

As will be clear from the foregoing, a shield electrode provided between coils (i.e., between primary and secondary windings) as means for reducing common-mode noise can be formed to be composed of a plurality of segments in the shape of concentric circles or concentric rings as seen in a plan view of a transformer chip, or in a spiral shape as seen in a plan view of a transformer chip.

Whichever layout pattern may be used, what matters in enhancing the effect of reducing common-mode noise is to increase the area of the overlap with a coil as seen in a plan view of a transformer chip.

While examples shown FIGS. 38 to 41 deal chiefly with the relationship of a secondary winding with a shield electrode, a similar description applies to the relationship of a primary winding with a shield electrode.

<Overview>

To follow is an overview of the various embodiments described above.

According to one aspect of what is disclosed herein, a transformer chip includes, for example: a first wiring layer; a second wiring layer different from the first wiring layer; a primary winding formed in the first wiring layer; a secondary winding formed in the second wiring layer so as to be magnetically coupled with the primary winding; and a shield electrode formed so as to be interposed between the primary and secondary windings. (A first configuration.)

In the transformer chip of the first configuration described above, the shield electrode may include: a first shield electrode connected to a first ground terminal of the primary winding; and a second shield electrode connected to a second ground terminal of the secondary winding. (A second configuration.)

In the transformer chip of the first or second configuration described above, the shield electrode may be formed to be composed of a plurality of segments thereof in a shape of concentric circles or concentric rings as seen in a plan view, or may be formed in a spiral shape as seen in a plan view. (A third configuration.)

In the transformer chip of the third configuration described above, the shield electrode may be formed in the shape of an open ring as seen in a plan view. (A fourth configuration.)

In the transformer chip of the third or fourth configuration described above, the shield electrode may be designed to have a line/space ratio equal to the line/space ratio of the primary or secondary winding. (A fifth configuration.)

In the transformer chip of any of the first to fifth configurations described above, the shield electrode may be formed up to outward of the outermost circumference of the primary or secondary winding. (A sixth configuration.)

In the transformer chip of any of the first to sixth configurations described above, the shield electrode nay be formed up to inward of the innermost circumference of the primary or secondary winding. (A seventh configuration.)

In the transformer chip of any of the first to seventh configurations described above, the shield electrode may be formed so as to trace the primary or secondary winding such that the shield electrode partly or wholly overlaps the primary or secondary winding. (An eighth configuration.)

In the transformer chip of the eighth configuration described above, the shield electrode may be configured to form open ends to inhibit occurrence of eddy currents. (A ninth configuration.)

According to another aspect of what is disclosed herein, a transformer chip includes, for example: a first wiring layer; a second wiring layer different from the first wiring layer; the primary windings of a first transformer and a second transformer, the primary windings being formed in the first wiring layer; the secondary windings of the first and second transformers, the secondary windings being formed in the second wiring layer so as to be magnetically coupled with the primary windings of the first and second transformers respectively; and shield electrodes formed so as to be interposed respectively between the primary and secondary windings of the first transformer and between the primary and secondary windings of the second transformer. (A tenth configuration.)

The transformer chip of the tenth configuration described above may further include: a first terminal to which the first terminal of the primary winding of the first transformer is connected; a second terminal to which the second terminal of the primary winding of the first transformer and the first terminal of the primary winding of the second transformer are connected; a third terminal to which the second terminal of the primary winding of the second terminal is connected; a fourth terminal to which the first terminal of the secondary winding of the first transformer is connected; a fifth terminal to which the second terminal of the secondary winding of the first transformer and the first terminal of the secondary winding of the second transformer are connected; and a sixth terminal to which the second terminal of the secondary winding of the second transformer is connected. (An eleventh configuration.)

According to yet another aspect of what is disclosed herein, a signal transmission device includes, for example: a controller chip; a driver chip; and the transformer chip according to any of the first to eleventh configurations described above configured to transmit a pulse signal while isolating between the controller chip and the driver chip. (A twelfth configuration.)

<Other Modifications>

The various technical features disclosed herein may be implemented in any manners other than as in the embodiments described above, and allow for many modifications without departure from the spirit of their technical ingenuity. For example, any bipolar transistor may be replaced with a MOS field-effect transistor and vice versa; the logic levels of any signal may be reversed. That is, the embodiments described above should be understood to be in every aspect illustrative and not restrictive, and the technical scope of the present invention is defined not by the description of the embodiments given above but by the appended claims and encompasses any modifications within a scope and sense equivalent to those claims.

### INDUSTRIAL APPLICABILITY

The invention disclosed herein finds use generally in applications that require signal transmission with reliable isolation between input and output (e.g., isolated gate drivers, motor drivers, isolators, or other ICs that handle high voltages).

### REFERENCE SIGNS LIST

5 semiconductor device
11, 11A-11F low-potential terminal
12, 12A-12F high-potential terminal
21, 21A-21D transformer
22 low-potential coil (primary coil)
23 high-potential coil (secondary coil)
24 first inner end
25 first outer end
26 first spiral portion
27 second inner end
28 second outer end
29 second spiral portion
31 first low-potential wiring
32 second low-potential wiring
33 first high-potential wiring
34 second high-potential wiring
41 semiconductor chip
42 first principal surface
43 second principal surface
44A-44D chip side wall
45 first functional device
51 insulation layer
52 insulation principal surface
53A-53D insulation side wall
55 bottom insulation layer
56 top insulation layer
57 interlayer insulation layer
58 first insulation layer
59 second insulation layer
60 second functional device
61 sealing conductor
62 device region
63 outer region
64 sealing plug conductor
65 sealing via conductor
66 first inner region
67 second inner region
71 through wiring
72 low-potential connection wiring
73 lead wiring
74 first connection plug electrode
75 second connection plug electrode
76 pad plug electrode
77 substrate plug electrode
78 first electrode layer
79 second electrode layer
80 wiring plug electrode
81 high-potential connection wiring
82 pad plug electrode
85 dummy pattern
86 high-potential dummy pattern
87 first high-potential dummy pattern
88 second high-potential dummy pattern
89 first region
90 second region
91 third region
92 first connection part
93 first pattern
94 second pattern
95 third pattern
96 first outer circumferential line
97 second outer circumferential line
98 first middle line
99 first connection line
100 slit
101 first branch portion
102 second branch portion
103 third peripheral line
104 second middle line
105 second connection line
106 slit
107 third branch portion
108 fourth branch portion
109 fourth peripheral line
110 third middle line
111 third connection line
112 slit
113 fifth branch portion
114 sixth branch portion
115 second connection part
116A-116F high-potential line
117 slit
121 floating dummy pattern
122A-122F floating line
130 separation structure
130A inner end part
130B outer end part
130C main body part
131 field insulation film
132 connection portion
140 inorganic insulation layer
141 first inorganic insulation layer
142 second inorganic insulation layer
143 low-potential pad opening
144 high-potential pad opening
145 organic insulation layer
146 first part
147 second part
148 low-potential terminal opening
149 high-potential terminal opening
200 signal transmission device
200p primary circuit system
200s secondary circuit system
210 controller chip (first chip)
211 pulse transmission circuit (pulse generator)
212, 213 buffer
220 driver chip (second chip)
221, 222 buffer
223 pulse reception circuit (RS flip-flop)
224 driver
225 noise canceller
230 transformer chip (third chip)
230a first wiring layer (lower layer)
230b second wiring layer (upper layer)
231, 232 transformer
231p, 232p primary coil (primary winding)
231s, 232s secondary coil (secondary winding)
300 transformer chip
301 first transformer
302 second transformer
303 third transformer
304 fourth transformer
305 first guard ring
306 second guard ring
400 transformer chip
401, 402 pad
403 coil
404, 405 shield electrode
404x, 405x open end
404y coupling portion
a1-a8 pad (corresponding to first current feed pad)
b1-b8 pad (corresponding to first voltage measurement pad)
c1-c4 pad (corresponding to second current feed pad)
d1-d4 pad (corresponding to second voltage measurement pad)
e1, e2 pad
AND1, AND2 AND gate
BUF1-BUF4 buffer
C, C1, C2 coil-to-coil capacitance
DLY1-DLY4 delay circuit
L1p, L2p, L3p, L4p primary coil
L1s, L2s, L3s, L4s secondary coil
1MT, 2MT, 3MT metal layer (wiring layer)
PSV passivation layer
SLD, SLD1, SLD2 shield electrode
T21, T22, T23, T24, T25, T26 external terminal
TMT pad
1VIA, 2VIA, TVIA via
X first direction
X21, X22, X23 internal terminal
Y second direction
Y21, Y22, Y23 wiring
Z normal direction
Z21, Z22, Z23 via
α, β ground terminal

1. A transformer chip, comprising:
a first wiring layer;
a second wiring layer different from the first wiring layer;
a primary winding formed in the first wiring layer;
a secondary winding formed in the second wiring layer so as to be magnetically coupled with the primary winding; and
a shield electrode formed so as to be interposed between the primary and secondary windings.

2. The transformer chip according to claim 1, wherein the shield electrode includes:
a first shield electrode connected to a first ground terminal of the primary winding; and
a second shield electrode connected to a second ground terminal of the secondary winding.

3. The transformer chip according to claim 1, wherein the shield electrode is formed
to be composed of a plurality of segments thereof in a shape of concentric circles or concentric rings as seen in a plan view or
in a spiral shape as seen in a plan view.

4. The transformer chip according to claim 3, wherein
the shield electrode is formed in a shape of an open ring as seen in a plan view.

5. The transformer chip according to claim 3, wherein
the shield electrode is designed to have a line/space ratio equal to a line/space ratio of the primary or secondary winding.

6. The transformer chip according to claim 1, wherein
the shield electrode is formed up to outward of an outermost circumference of the primary or secondary winding.

7. The transformer chip according to claim 1, wherein
the shield electrode is formed up to inward of an innermost circumference of the primary or secondary winding.

8. The transformer chip according to claim 1, wherein
the shield electrode is formed so as to trace the primary or secondary winding such that the shield electrode partly or wholly overlaps the primary or secondary winding.

9. The transformer chip according to claim 8, wherein
the shield electrode is configured to form open ends to inhibit occurrence of eddy currents.

10. A transformer chip, comprising:
a first wiring layer;
a second wiring layer different from the first wiring layer;
primary windings of a first transformer and a second transformer, the primary windings being formed in the first wiring layer;
secondary windings of the first and second transformers, the secondary windings being formed in the second wiring layer so as to be magnetically coupled with the primary windings of the first and second transformers respectively; and
shield electrodes formed so as to be interposed respectively between the primary and secondary windings of the first transformer and between the primary and secondary windings of the second transformer.

11. The transformer chip according to claim 10, further comprising:
a first terminal to which a first terminal of the primary winding of the first transformer is connected;
a second terminal to which a second terminal of the primary winding of the first transformer and a first terminal of the primary winding of the second transformer are connected;
a third terminal to which a second terminal of the primary winding of the second terminal is connected;
a fourth terminal to which a first terminal of the secondary winding of the first transformer is connected;
a fifth terminal to which a second terminal of the secondary winding of the first transformer and a first terminal of the secondary winding of the second transformer are connected; and
a sixth terminal to which a second terminal of the secondary winding of the second transformer is connected.

12. A signal transmission device, comprising:
a controller chip;
a driver chip; and
the transformer chip according to claim 1 configured to transmit a pulse signal while isolating between the controller chip and the driver chip.

13. A signal transmission device, comprising:
a controller chip;
a driver chip; and
the transformer chip according to claim 10 configured to transmit a pulse signal while isolating between the controller chip and the driver chip.
